(19) United States
(12) Patent Application Publication
(10) Pub. No.: US 2026/0214919 A1
(43) Pub. Date: Jul. 23, 2026

(54) SEMICONDUCTOR DEVICE

(71) Applicant: ROHM CO., LTD., Kyoto (JP)

(72) Inventors: Kazumasa NISHIO, Kyoto (JP); Kosaku ADACHI, Kyoto (JP)

(73) Assignee: ROHM CO., LTD., Kyoto (JP)

(21) Appl. No.: 19/570,776

(22) Filed: Mar. 18, 2026

Related U.S. Application Data
(63) Continuation of application No. PCT/JP2024/034018, filed on Sep. 24, 2024.

(30) Foreign Application Priority Data
Sep. 29, 2023 (JP) 2023-169592

(51) Int. Cl. H10D 1/47; H10D 80/20; H10D 80/30; H10W 90/00; H10W 90/10

(52) U.S. Cl. CPC H10D 1/474; H10D 80/213; H10D 80/30; H10W 90/10; H10W 90/753; H10W 90/756; H10W 90/811

(57) ABSTRACT

A semiconductor device includes a semiconductor substrate, an insulating layer provided on the semiconductor substrate, a resistor embedded in the insulating layer and formed by electrically connecting a plurality of resistance layers, a first electrode connected electrically to a first end of the resistor, a second electrode connected electrically to a second end of the resistor, and a plurality of first dummy wiring lines arranged around the first electrode and respectively coupled capacitively to the plurality of resistance layers in the resistor.

### CROSS-REFERENCE TO RELATED APPLICATIONS

This application is a continuation application of PCT Application No. PCT/JP 2024/034018, filed on Sep. 24, 2024, which claims the benefit of priority from Japanese Patent Application No. 2023-169592, filed on Sep. 29, 2023. The entire contents of the above listed PCT and priority applications are incorporated herein by reference.

### TECHNICAL FIELD

The present disclosure relates to a semiconductor device.

### BACKGROUND ART

International Publication No. WO2023/085026 discloses a semiconductor device including a plurality of resistor elements.

### BRIEF DESCRIPTION OF THE DRAWINGS

FIG. 1 is a plan view of a semiconductor package.

FIG. 2 is a circuit diagram of a resistor chip and an amplifier chip.

FIG. 3 is a graph showing a relationship between an input voltage HV (kV) and an output voltage Vout (V).

FIG. 4 is a diagram showing a planar configuration for explaining an electrical connection relationship of a voltage divider circuit formed in the resistor chip.

FIG. 5 is a diagram showing an example of a detailed structure of a resistor portion in the voltage divider circuit formed in the resistor chip.

FIG. 6 is a diagram showing a vertical sectional configuration of a portion along line A-A in FIG. 5.

FIG. 7 is a diagram showing a vertical sectional configuration of a portion along line B-B in FIG. 5.

FIG. 8 is a diagram showing a vertical sectional configuration of a portion along line C-C in FIG. 5.

FIG. 9 is a diagram showing a vertical sectional configuration of a portion along line D-D in FIG. 5.

FIG. 10 is a diagram showing a planar configuration for explaining an electrical connection relationship of a voltage divider circuit formed in the resistor chip.

FIG. 11 is a perspective view of a coupling portion indicated by a first region S1 in FIG. 10.

FIG. 12A is a vertical cross-sectional view of the coupling portion shown in FIG. 11.

FIG. 12B is a plan view of the coupling portion shown in FIG. 11.

FIG. 13A is a plan view of a modified coupling portion.

FIG. 13B is a plan view of a modified coupling portion.

FIG. 13C is a plan view of a modified coupling portion.

FIG. 14 is a plan view of dummy wiring lines located near a substrate edge.

FIG. 15 is a diagram showing a planar configuration for explaining an electrical connection relationship of a voltage divider circuit formed in the resistor chip.

FIG. 16 is a diagram showing a planar configuration for explaining an electrical connection relationship of a voltage divider circuit formed in the resistor chip.

FIG. 17 is a diagram showing a planar configuration for explaining an electrical connection relationship of a voltage divider circuit formed in the resistor chip.

FIG. 18 is a perspective view of a connection portion indicated by a second region S2 in FIG. 17.

FIG. 19A is a vertical cross-sectional view of the connection portion shown in FIG. 18.

FIG. 19B is a plan view of the connection portion shown in FIG. 18.

FIG. 20A is a plan view of a modified connection portion.

FIG. 20B is a plan view of a modified connection portion.

FIG. 21A and FIG. 21B are charts showing a breakdown voltage (kV) obtained with a sample element.

FIG. 22 is a plan view of a modified structure of a voltage divider circuit portion in a resistor chip.

FIG. 23A is a plan view of capacitively coupled dummy wiring lines near a first electrode

FIG. 23B is a plan view of electrically connected dummy wiring lines near the first electrode.

FIG. 24 is a plan view of a resistor chip including capacitively coupled dummy wiring lines.

FIG. 25 is a plan view of a resistor chip including electrically connected dummy wiring lines.

FIG. 26 is a diagram showing a vertical sectional configuration (first modification) of a portion along line A-A in FIG. 4.

FIG. 27 is a diagram showing a vertical sectional configuration (second modification) of a portion along line A-A in FIG. 4.

### DETAILED DESCRIPTION

Hereinafter, various exemplary embodiments will be described in detail with reference to the drawings. In each drawing, the same or corresponding parts are denoted by the same reference numerals, and redundant descriptions are omitted.

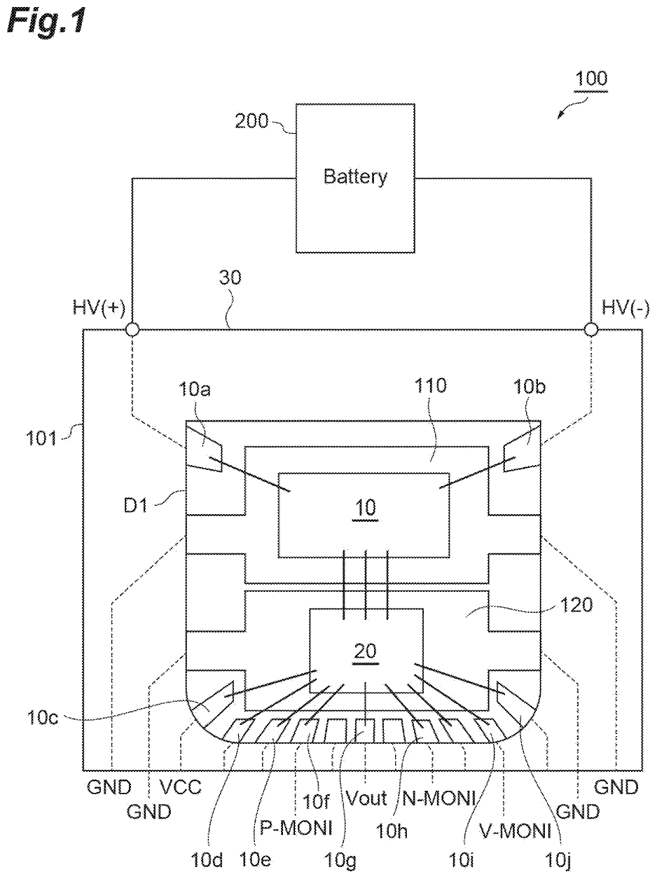

FIG. 1 is a plan view of a semiconductor package. The figure shows a state in which an upper lid member is removed.

The semiconductor package 100 includes a case 101 having a recess D1. Case 101 is made of an insulating material such as a resin or a ceramic. The depth direction of the recess D1 is a thickness direction of the semiconductor package 100.

The semiconductor package 100 includes a resistor chip 10 (semiconductor device) disposed on a first die pad 110 in the recess D1, and an amplifier chip 20 (semiconductor device) disposed on a second die pad 120 in the recess D1. An opening end of the recess D1 of the semiconductor package 100 is sealed with a lid member (not shown), and inside the recess D1 is a sealed space. The material of the lid member may be an insulating material such as resin, and the interior of recess D1 may be filled with a gas or an insulating material. Ground potential (GND) is applied to the first die pad 110 and the second die pad 120 via the lead frame.

A lower surface of the resistor chip 10 is fixed to the first die pad 110. An upper surface of the resistor chip 10 is electrically connected to a first inner lead 10a and a second inner lead 10b of a lead frame via bonding wires. The first inner lead 10a is electrically connected to a first input terminal HV(+). The second inner lead 10b is electrically connected to a second input terminal HV(−). The first inner lead 10a and the second inner lead 10b are outer leads exposed outside the package. The first input terminal HV(+) is electrically connected to a positive electrode of a battery 200. The second input terminal HV(−) is electrically connected to a negative electrode of the battery 200.

A lower surface of the amplifier chip 20 is fixed to the second die pad 120. An upper surface of the amplifier chip 20 is electrically connected to a third inner lead 10c, a fourth inner lead 10d, a fifth inner lead 10e, a sixth inner lead 10f, a seventh inner lead 10g, an eighth inner lead 10h, a ninth inner lead 10i, and a tenth inner lead 10j of the lead frame via bonding wires. Note that a connection in an electric circuit means an electrical connection, and when it is clear that an electrical connection is made by a physical connection, the term “connection” may be simply used to avoid redundancy of expression.

A power supply potential VCC is applied to the third inner lead 10c. A positive monitor signal P-MONI is output from the sixth inner lead 10f. The seventh inner lead 10g is connected to an output terminal as an outer lead, and an output voltage Vout is output. A negative monitor signal N-MONI is output from the eighth inner lead 10h. A voltage monitor signal V-MONI is output from the ninth inner lead 10i. Note that symbols of these signals also mean reference signs indicating terminals as outer leads corresponding to the signals. The fourth inner lead 10d, the fifth inner lead 10e, and the tenth inner lead 10j can be used for preliminary functions.

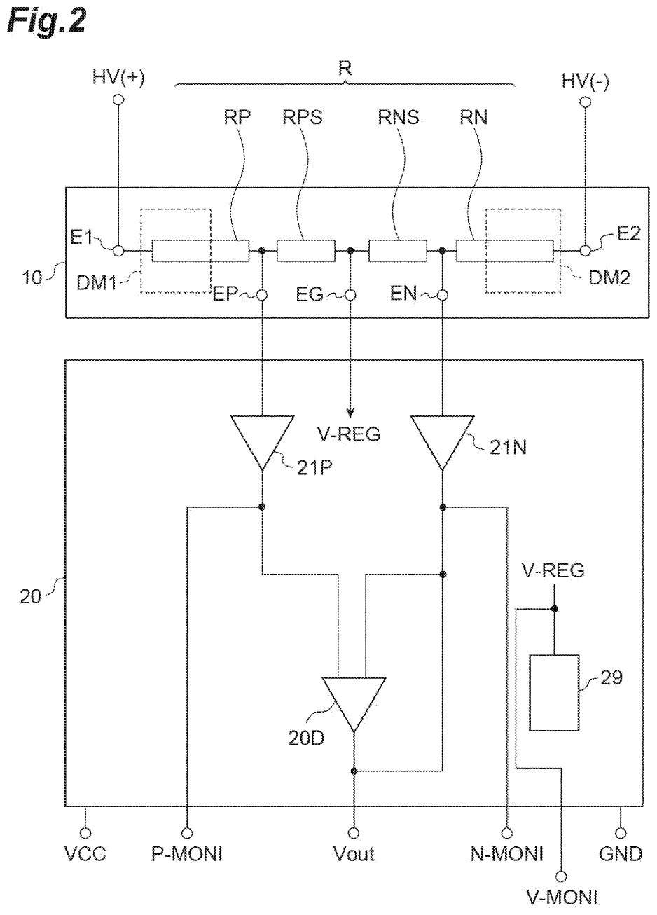

FIG. 2 is a circuit diagram of the resistor chip 10 and the amplifier chip 20.

The resistor chip 10 constitutes a voltage divider circuit including a resistor R (resistance pattern). The resistor R includes a first resistor RP electrically connected to a first electrode E1, and a second resistor RN electrically connected to a second electrode E2. The resistor R includes a voltage detection resistor (RPS, RNS) that electrically connects the first resistor RP and the second resistor RN and has a resistance value lower than both the first resistor RP and the second resistor RN. The resistor chip 10 includes a first output electrode EP, a second output electrode EN, and a reference electrode EG, which are electrically connected to different locations of the voltage detection resistor (RPS, RNS), respectively. The voltage detection resistor (RPS, RNS) includes a first voltage detection resistor RPS and a second voltage detection resistor RNS.

The first resistor RP is connected between the first electrode E1 and the first output electrode EP. The second resistor RN is connected between the second electrode E2 and the second output electrode EN. The first voltage detection resistor RPS is connected between the first output electrode EP and the reference electrode EG. The second voltage detection resistor RNS is connected between the second output electrode EN and the reference electrode EG. A resistance value RRPS of the first voltage detection resistor RPS is smaller than a resistance value R_{RP} of the first resistor RP (R_{RPS}<R_{RP}). A resistance value R_{RNS} of the second voltage detection resistor RNS is smaller than a resistance value R_{RN} of the second resistor RN (R_{RNS}<R_{RN}). The resistance value of the detection resistor can be set, for example, to 1/100 or less of the resistance value of the corresponding resistor (R_{RPS}≤1%×R_{RP}, R_{RNS}≤1%×R_{RN}). This ratio can also be set to satisfy values such as, for example, R_{RPS}≤0.5%×R_{RP}, R_{RNS}≤0.5%×R_{RN}, or R_{RPS}≤0.2%×R_{RP}, R_{RNS}≤0.2%×R_{RN}. When an input voltage is applied between the first electrode E1 and the second electrode E2, the input voltage is divided according to a ratio of the resistance values of the respective resistors.

For example, assume that the input voltage is given by input voltage=1000 V, and the resistance value of the resistor R (series combined resistance value of each resistor) is given by resistance value=k×1000 MΩ·k is a positive value, and for example, k=0.5. Also, assume that the resistance value of the first resistor RP is given by RP=k×499.5 MΩ, the resistance value of the first voltage detection resistor RPS is given by RPS=k×0.5 MΩ, the resistance value of the second resistor RN is given by RN=k×499.5 MΩ, and the resistance value of the second voltage detection resistor RNS is given by RNS=k×0.5 MΩ.

In this case, a voltage of 499.5 V is applied across the first resistor RP, a voltage of 0.5 V is applied across the first voltage detection resistor RPS, a voltage of 499.5 V is applied across the second resistor RN, and a voltage of 0.5 V is applied across the second voltage detection resistor RNS. A voltage of 0.5 V is applied between the reference electrode EG and the first output electrode EP, and a voltage of 0.5 V is applied between the reference electrode EG and the second output electrode EN. A voltage of 1 V is applied between the first output electrode EP and the second output electrode EN. In other words, the resistor chip 10 constituting the voltage divider circuit can have an output voltage=1 V when the input voltage=1000 V. Of course, when the input voltage=500 V, the output voltage can be 0.5 V. The resistance value of the resistor R between the first electrode E1 and the second electrode E2 can also be 1 MΩ or more and 1000 MΩ or less. The resistance value of the resistor R can also be 100 MΩ or more and 800 MΩ or less. The resistance value of the resistor R can also be 300 MΩ or more and 600 MΩ or less. This resistance value may be any resistance value that has resistance to high voltage and allows voltage detection.

The amplifier chip 20 is a differential amplifier circuit and includes a differential amplifier 20D. A positive signal output from the first output electrode EP and a negative signal output from the second output electrode EN are input to the differential amplifier 20D, and a difference between these signals is output as an output voltage Vout.

The first output electrode EP is connected to a first voltage follower 21P via a bonding wire.

The second output electrode EN is connected to a second voltage follower 21N via a bonding wire.

The power supply potential VCC is supplied to the amplifier chip 20.

An output signal of the first voltage follower 21P is output to the outside of the amplifier chip 20 as a positive monitor signal P-MONI. An output signal of the second voltage follower 21N is output to the outside of the amplifier chip 20 as a negative monitor signal N-MONI. The reference electrode EG has a reference potential V-REG and is connected to a second voltage adjustment circuit 29 via a bonding wire. The second voltage adjustment circuit 29 generates a reference potential V-REG that is ½ of the power supply potential VCC. The reference potential V-REG is output to the outside of the amplifier chip 20 as a voltage monitor signal V-MONI.

A first dummy wiring line region DM1 is arranged around the first resistor RP. The first dummy wiring line region DM1 includes a plurality of dummy wiring lines (dummy electrodes, dummy wiring line patterns, dummy metals, dummy conductors). A second dummy wiring line region DM2 is arranged around the second resistor RN. The second dummy wiring line region DM2 includes a plurality of dummy wiring lines (dummy electrodes, dummy wiring line patterns, dummy metals, dummy conductors). The dummy wiring lines do not contribute to transmission of an input signal (input voltage), but they contribute to an increase in breakdown voltage in the resistor chip 10.

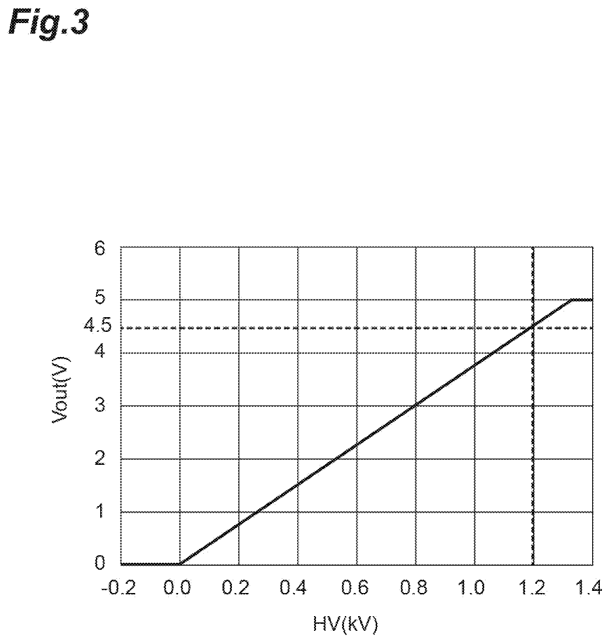

FIG. 3 is a graph showing a relationship between the input voltage HV (kV) and the output voltage Vout (V).

The input voltage HV (kV) is a difference (=V1−V2≈2×V1) between a positive first voltage V1 applied to the first input terminal HV(+) in FIG. 2 and a negative second voltage V2 applied to the second input terminal HV(−). For example, when the positive first voltage V1=600 V and the negative second voltage V2=−600 V, the input voltage HV (kV)=1.2 (kV). In this case, a detection voltage (a voltage between the first output electrode EP and the second output electrode EN) in the resistor chip 10 shown in FIG. 2 is, for example, 1.2 V (= 1/1000 of the input voltage). The amplifier chip 20 amplifies the detection voltage and outputs it as the output voltage Vout (V). The input voltage HV (kV) and the output voltage Vout (V) have a linear relationship with a slope a (Vout (V)=a×HV (kV)). For example, when an amplification factor of the amplifier chip 20 is 3.75 times, the output voltage Vout=3.75×1.2 V=4.5 V.

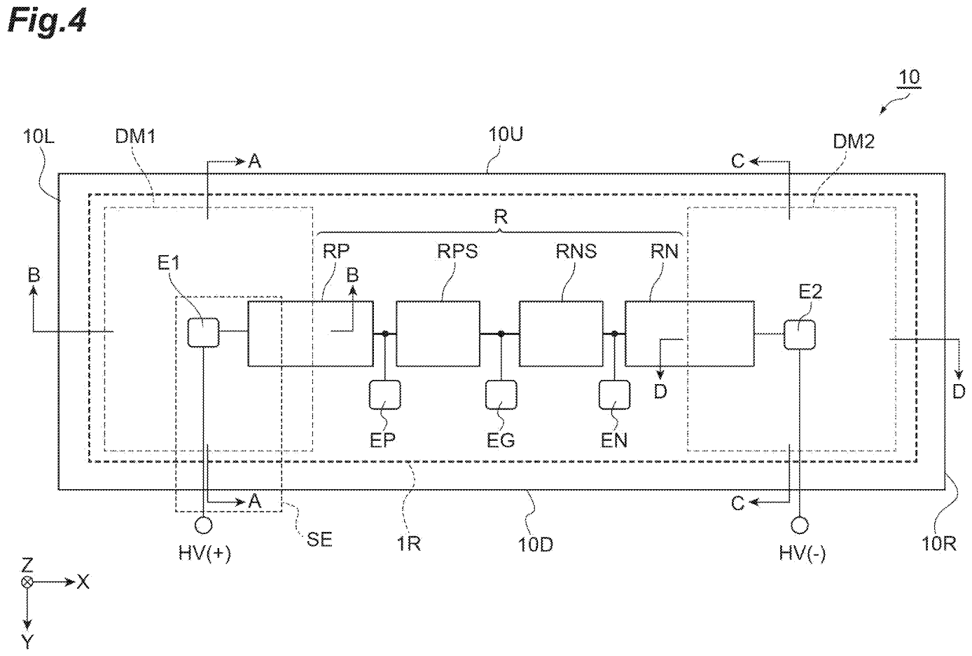

FIG. 4 is a diagram showing a planar configuration for explaining an electrical connection relationship of a voltage divider circuit formed in a resistor chip. An XYZ three-dimensional orthogonal coordinate system is set. The thickness direction of the resistor chip is defined as the Z-axis direction, a direction perpendicular to the Z-axis direction is defined as the X-axis direction, and a direction perpendicular to both the Z-axis and the X-axis is defined as the Y-axis direction. The positive direction of the Z-axis is the depth direction of the resistor chip. The direction of the X-axis is the longitudinal direction of the resistor chip. The direction of the Y-axis is the width direction of the resistor chip. The resistor chip shown in this embodiment is an example and can take various forms. Dimensions, arrangement, and orientation of each element in the resistor chip can be changed as necessary, and it is also possible to integrate it with an amplifier chip or the like.

A positive first potential is applied to the first electrode E1 of the resistor chip 10 from a first input terminal HV(+), and a negative second potential is applied to the second electrode E2 from a second input terminal HV(−). Between the first electrode E1 and the second electrode E2, the first resistor RP, the first voltage detection resistor RPS, the second voltage detection resistor RNS, and the second resistor RN are connected in series. The planar shape (XY planar shape) of the resistor chip 10 is a rectangle having four side surfaces (edges: 10U, 10L, 10R, 10D), and a ring-shaped conductor 1R is formed along each side surface. In a plan view, there is a gap between these side surfaces and the ring-shaped conductor 1R. In a plan view, the first dummy wiring line region DM1, the first electrode E1, the first resistor RP, the first voltage detection resistor RPS, the second voltage detection resistor RNS, the second resistor RN, the second electrode E2, the first output electrode EP, the second output electrode EN, and the reference electrode EG are arranged inside the ring-shaped conductor 1R. The ring-shaped conductor 1R suppresses intrusion of moisture into the insulating layer in which the resistance layer and the electrodes are embedded and penetration of cracks generated by dicing. Note that the ring-shaped conductor 1R may be omitted.

The first output electrode EP is connected to a connection point (node) between the first resistor RP and the first voltage detection resistor RPS. The second output electrode EN is connected to a connection point (node) between the second resistor RN and the second voltage detection resistor RNS. The reference electrode EG is connected to a connection point (node) between the first voltage detection resistor RPS and the second voltage detection resistor RNS. These connection points can be configured from buried electrodes that connect between the resistors.

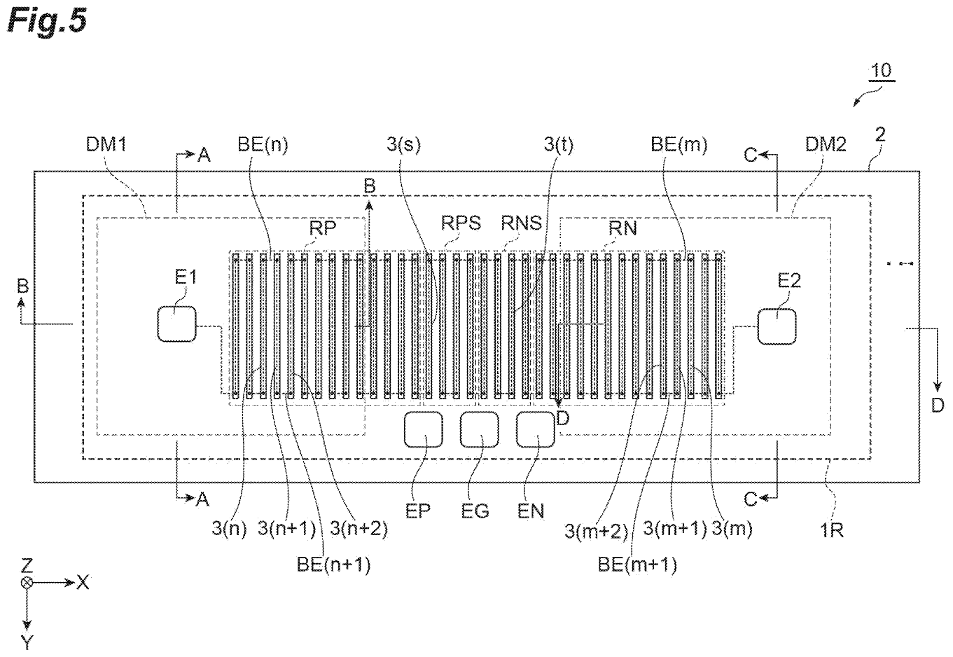

FIG. 5 is a diagram showing an example of a detailed structure of a resistor portion in the voltage divider circuit formed in the resistor chip.

The first resistor RP includes a plurality of linear resistors 3(n) (resistance layers) (n is a natural number (1, 2, 3 . . . )). The linear resistor is a resistor extending linearly. In this example, each linear resistor included in the entire resistor extends along the Y-axis direction. One end of the linear resistor 3(n) and one end of an adjacent linear resistor 3(n+1) are electrically connected by a via electrode and a buried electrode for connection BE(n). The other end of the linear resistor 3(n+1) and the other end of an adjacent linear resistor 3(n+2) are electrically connected by a via electrode and a buried electrode for connection BE(n+1). The order (n) related to the first resistor RP increases in a direction away from the first electrode E1.

The second resistor RN includes a plurality of linear resistors 3(m) (resistance layers) (m is a natural number (1, 2, 3 . . . )). The linear resistor is a resistor extending linearly. In this example, n=m. A connection relationship of the plurality of linear resistors 3(m) is the same as a connection relationship of the plurality of linear resistors 3(n). One end of the linear resistor 3(m) and one end of an adjacent linear resistor 3(m+1) are electrically connected by a via electrode and a buried electrode for connection BE(m). The other end of the linear resistor 3(m+1) and the other end of an adjacent linear resistor 3(m+2) are electrically connected by a via electrode and a buried electrode for connection BE(m+1). The order (m) related to the second resistor RN increases in a direction away from the second electrode E2.

The first voltage detection resistor RPS includes a plurality of linear resistors 3(s) (resistance layers) (s is a natural number (1, 2, 3 . . . )). The linear resistor is a resistor extending linearly. In this example, s<n. Except for the smaller number of linear resistors, a connection relationship of the plurality of linear resistors 3(s) is the same as a connection relationship of the plurality of linear resistors 3(n), and adjacent linear resistors are electrically connected by a via electrode and a buried electrode for connection. The order (s) related to the first voltage detection resistor RPS may be increased in a direction away from the first electrode E1. The number of the plurality of linear resistors 3(s) is considerably smaller than the number of the linear resistors 3(n). The maximum value of s can be set, for example, in the range 1 to 10.

The second voltage detection resistor RNS includes a plurality of linear resistors 3(t) (resistance layers) (t is a natural number (1, 2, 3 . . . )). The linear resistor is a resistor extending linearly. In this example, t<m and t=s. Except for the smaller number of linear resistors, a connection relationship of the plurality of linear resistors 3(t) is the same as a connection relationship of the plurality of linear resistors 3(m), and adjacent linear resistors are electrically connected by a via electrode and a buried electrode for connection. The order (t) related to the second voltage detection resistor RNS may be increased in a direction away from the second electrode E2. The number of the plurality of linear resistors 3(t) is considerably smaller than the number of the linear resistors 3(m). The maximum value of t can be set, for example, in the range of 1 to 10.

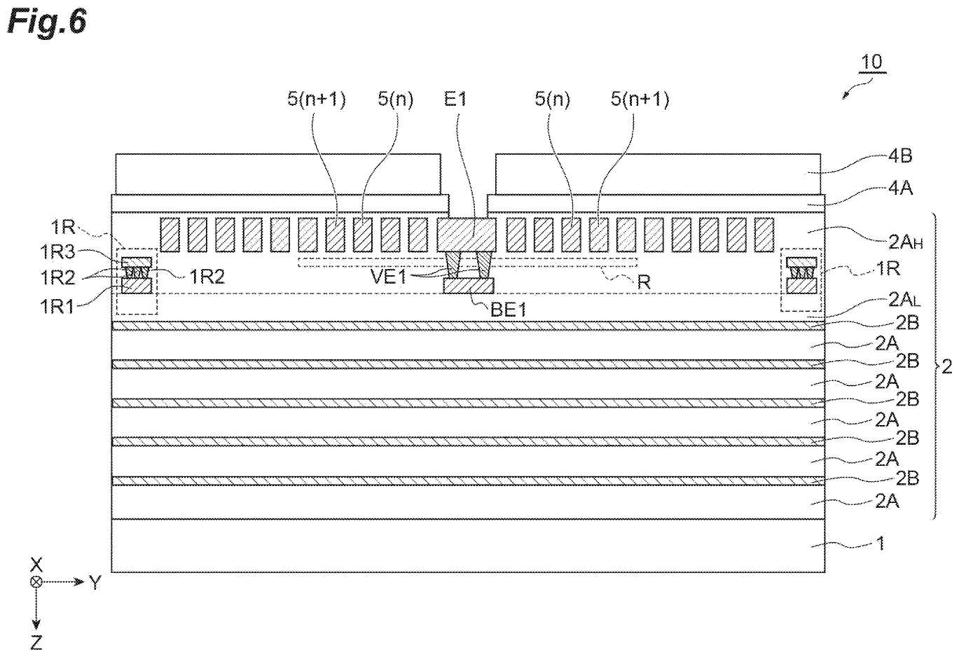

FIG. 6 is a diagram showing a vertical sectional configuration (YZ cross section) of a portion along line A-A in FIG. 5.

The resistor chip 10 (a semiconductor device) includes a semiconductor substrate 1, an insulating layer 2, a resistor R, a first electrode E1, and a plurality of first dummy wiring lines 5(n) (first dummy wiring line region).

The semiconductor substrate 1 can have conductivity. For example, an impurity concentration of the semiconductor substrate 1 may be 5×10¹³ (cm⁻³ ) or more and 5×10¹⁴ (cm⁻³ ) or less. A thickness of the semiconductor substrate 1 may be 50 μm or more and 800 μm or less. As a material of the semiconductor substrate 1, silicon (Si) can be used, but a compound semiconductor such as SiC or SiGe can also be used.

The insulating layer 2 is provided on the semiconductor substrate 1. The insulating layer 2 includes a plurality of stacked dielectric layers (a first dielectric layer 2A, a second dielectric layer 2B). A material of at least one layer (the first dielectric layer 2A) of the plurality of dielectric layers includes silicon oxide. A material of at least one layer (the second dielectric layer 2B) of the plurality of dielectric layers includes silicon nitride. In this example, the first dielectric layer 2A and the second dielectric layer 2B are alternately stacked. The silicon oxide in this example is SiO₂, but an elemental composition ratio may be changed as necessary, and other elements may be included. The silicon nitride in this example is Si₃N₄, but an elemental composition ratio may be changed as necessary, and other elements may be included. The thickness of the insulating layer 2 may be, for example, 5 μm or more and 50 μm or less.

The insulating layer 2 includes a lower dielectric layer 2A_{L} formed on the uppermost second dielectric layer 2B, and an upper dielectric layer 2A_{H} formed on the lower dielectric layer 2A_{L}. An exemplary material of the lower dielectric layer 2A_{L} and the upper dielectric layer 2A_{H} is the same as that of the first dielectric layer 2A. The first protective film 4A is formed on the upper dielectric layer 2A_{H}. As a material of the first protective film 4A, an inorganic insulator such as silicon oxide or silicon nitride can be used. A second protective film 4B is formed on the first protective film 4A. As a material of the second protective film 4B, a resin (insulator) such as polyimide can be used. In a region directly above the first electrode E1, the upper dielectric layer 2A_{H}, the first protective film 4A, and the second protective film 4B are removed, and an upper surface of the first electrode E1 is exposed. A wiring line (bonding wire, wiring line pattern) is connected to the upper surface of the first electrode E1 (electrode pad).

The resistor R is embedded in the insulating layer 2 and is formed by electrically connecting a plurality of resistance layers (linear resistors). The resistor R (plurality of linear resistors: resistance layers) is made of a resistance material having a higher resistivity than polysilicon. Specifically, the material of the resistor R (resistance layer) is a material containing chromium (Cr) and silicon (Si), and is CrSi, CrSiC, or CrSiN. Other materials can also be used. That is, the material of the resistance layer constituting the resistor R can specifically include at least one metal compound selected from the group consisting of CrSi, CrSiN, CrSiO, TaN, and TiN. The resistance layer constituting the resistor R can be formed using a sputtering method or the like using a target containing a resistance material. A plating method can also be used depending on the type of material of the resistor R. The material of the resistor R may be composed of a single resistance material, or a combination of a plurality of resistance materials. The thickness Rd of each resistance layer constituting the resistor R can be set in the range of 1 nm≤Rd≤5 nm. When the thickness Rd is equal to or less than an upper limit value, the resistance value can be made sufficiently high, and when it is equal to or more than a lower limit value, the resistance and strength of the resistance layer can be maintained.

The first electrode E1 is electrically connected to a first end (an end in the X-axis direction) of the resistor R. The lower surface of the first electrode E1 is connected to an upper surface of a first buried electrode BE1 via a first via electrode VE1 extending downward in the upper dielectric layer 2A_{H}. The first buried electrode BE1 extends horizontally in the upper dielectric layer 2A_{H}, and an end thereof is connected to a lower surface of one end of the resistance layer constituting the resistor R via a second via electrode (not shown). Although the resistance layer is thin, it can be easily brought into contact with the via electrode by forming the resistance layer after forming the second via electrode. As a material of the first electrode E1, a metal material such as Al (aluminum) or Cu (copper) can be used. The material of the various dummy wiring lines may include Al, Cu, W, or Ti, and these have lower resistivity than the resistance layer. As a material of the first via electrode VE1, a refractory metal such as tungsten (W) can be used, but other electrode materials can also be used. The via electrode and the resistance layer are embedded in the insulating layer 2.

The plurality of first dummy wiring lines 5(n) is formed in the first dummy wiring line region DM1 (FIG. 5) described above. The plurality of first dummy wiring lines 5(n) is arranged around the first electrode E1 in a plan view, and each first dummy wiring line is capacitively coupled to a corresponding resistance layer or layers in the resistor R.

The resistor chip 10 includes a ring-shaped conductor 1R embedded in an upper region of the insulating layer 2. The ring-shaped conductor 1R includes a peripheral electrode 1R1, a peripheral via electrode IR2, and a peripheral resistor 1R3. The peripheral via electrode 1R2 connects an upper surface of the peripheral electrode 1R1 and a lower surface of the peripheral resistor 1R3. The material of the peripheral electrode 1R1 may be the same as a material of the first buried electrode BE1. The material of the peripheral via electrode 1R2 may be the same as the material of the first via electrode VE1. A material of a resistance layer constituting the peripheral resistor 1R3 may be the same as a material of the resistor R. The planar shape of the peripheral resistor 1R3 can be a continuous annular shape or a discontinuous annular shape. When the shape of the peripheral resistor 1R3 is an annular shape formed by intermittently arranging a plurality of linear resistors, the peripheral electrode 1R1 may connect ends of adjacent linear resistors via the peripheral via electrode 1R2.

The first buried electrode BE1 and the peripheral electrode 1R1 are formed on the lower dielectric layer 2 AL and are embedded in the insulating layer 2.

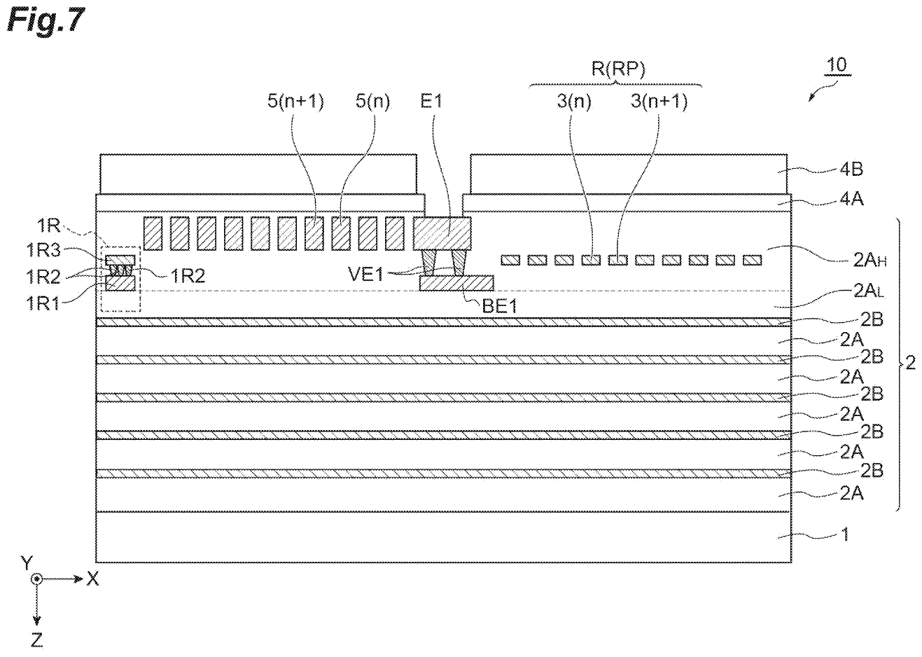

FIG. 7 is a diagram showing a vertical sectional configuration (XZ cross section) of a portion along line B-B in FIG. 5.

The resistor R (first resistor RP) includes a plurality of linear resistors 3(n). Each linear resistor 3(n) extends along the Y-axis. The plurality of linear resistors 3(n) are aligned along the X-axis. One end of the linear resistor 3(n) and one end of an adjacent linear resistor 3(n+1) are electrically connected via a via electrode and a buried electrode formed on the lower dielectric layer 2A_{L}. This connection structure is the same as the connection structure of the ring-shaped conductor 1R.

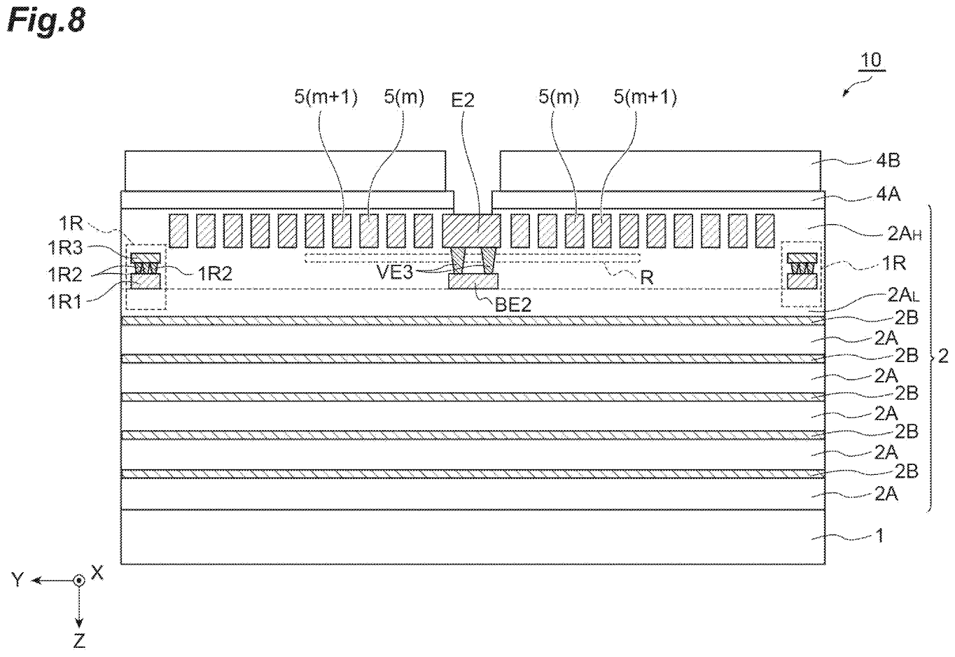

FIG. 8 is a diagram showing a vertical sectional configuration (YZ cross section) of a portion along line C-C in FIG. 5.

The resistor chip 10 includes a second electrode E2 and a plurality of second dummy wiring lines 5(m).

The second electrode E2 is electrically connected to a second end (an end in the X-axis direction) of the resistor R. The lower surface of the second electrode E2 is connected to an upper surface of a second buried electrode BE2 via a third via electrode VE3 extending downward in the upper dielectric layer 2A_{H}. The second buried electrode BE2 extends horizontally in the upper dielectric layer 2A_{H}, and an end thereof is connected to a lower surface of one end of the resistance layer constituting the resistor R via a fourth via electrode (not shown). Although the thickness of the resistance layer is thin, it can be easily brought into contact with the via electrode by forming the resistance layer after forming the fourth via electrode. As a material of the second electrode E2, a metal material such as Al (aluminum) or Cu (copper) can be used. As a material of the third via electrode VE3, a refractory metal such as tungsten (W) can be used, but other electrode materials can also be used.

The plurality of second dummy wiring lines 5(m) is formed in the second dummy wiring line region DM2 (FIG. 5) described above. The plurality of second dummy wiring lines 5(m) is arranged around the second electrode E2 in a plan view, and each second dummy wiring line is capacitively coupled to a corresponding resistance layer or layers in the resistor R.

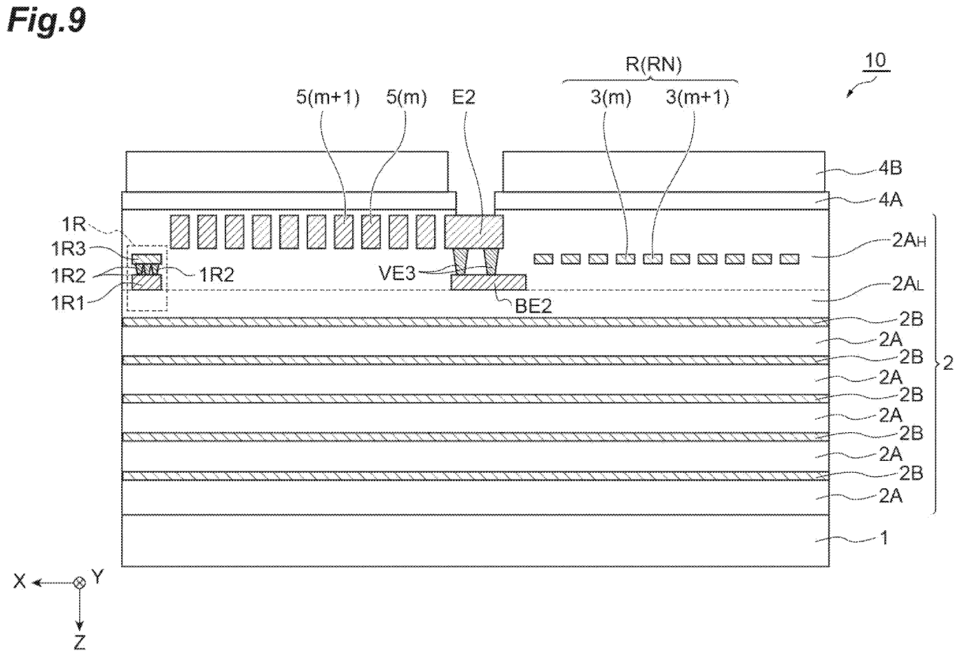

FIG. 9 is a diagram showing a vertical sectional configuration (XZ cross section) of a portion along line D-D in FIG. 5.

The resistor R (second resistor RN) includes a plurality of linear resistors 3(m). Each linear resistor 3(m) extends along the Y-axis. The plurality of linear resistors 3(m) are aligned along the X-axis. One end of the linear resistor 3(m) and one end of an adjacent linear resistor 3(m+1) are electrically connected via a via electrode and a buried electrode formed on the lower dielectric layer 2A_{L}. This connection structure is the same as the connection structure of the ring-shaped conductor 1R.

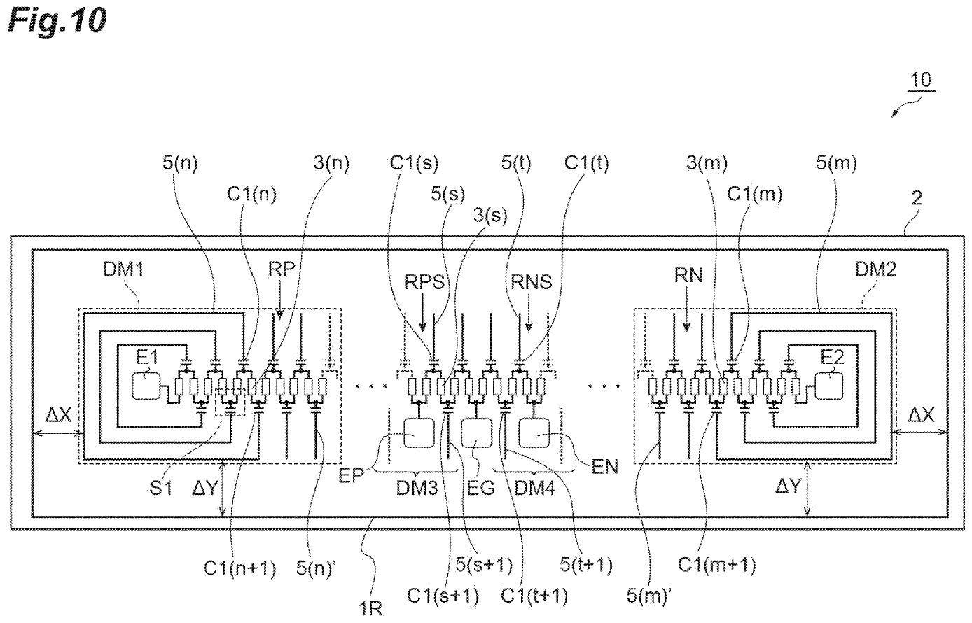

FIG. 10 is a diagram showing a planar configuration for explaining an electrical connection relationship of a voltage divider circuit formed in the resistor chip 10.

A first dummy wiring line region DM1 is formed around the first resistor RP. The first dummy wiring line region DM1 includes a plurality of first dummy wiring lines 5(n), and one end of each first dummy wiring line 5(n) is coupled to one end of a linear resistor 3(n) via a first capacitor C1(n). The other end of each first dummy wiring line 5(n) is coupled to the other end of the linear resistor 3(n) via the next first capacitor C1(n+1). A first dummy wiring line (e.g., first dummy wiring line 5(n)′) located at a position away from the first electrode E1 is coupled only to one end of the linear resistor via a capacitor and is not coupled to the other end.

A second dummy wiring line region DM2 is formed around the second resistor RN. The second dummy wiring line region DM2 includes a plurality of second dummy wiring lines 5(m), and one end of each second dummy wiring line 5(m) is coupled to one end of a linear resistor 3(m) via a first capacitor C1(m). The other end of each second dummy wiring line 5(m) is coupled to the other end of the linear resistor 3(m) via the next second capacitor C1(m+1). A second dummy wiring line (e.g., second dummy wiring line 5(m)′) that is located at a position away from the second electrode E2 is coupled only to one end of the linear resistor via a capacitor and is not coupled to the other end.

Since one end and the other end of the dummy wiring line 5, which are affected by an electric field around the first electrode E1 or the second electrode E2, are not electrically connected to the linear resistor 3, an influence of a potential difference generated between both ends of the linear resistor 3 is suppressed.

A third dummy wiring line region DM3 can be formed around the first voltage detection resistor RPS. The third dummy wiring line region DM3 includes a plurality of third dummy wiring lines 5(s), and one end of each third dummy wiring line 5(s) is coupled to one end of a linear resistor 3(s) via a third capacitor C1(s). Each third dummy wiring line 5(s) is coupled only to one end of the linear resistor via a capacitor and is not coupled to the other end. One end of a third dummy wiring line 5(s+1) located next to the third dummy wiring line 5(s) is coupled to the other end of the linear resistor 3(s) via a third capacitor C1(s+1). One end of at least one linear resistor 3(s) is connected to the first output electrode EP. A configuration in which the first output electrode EP is arranged inside the third dummy wiring line region DM3 is also possible, but the first output electrode EP does not have to be arranged there.

A fourth dummy wiring line region DM4 can be formed around the second voltage detection resistor RNS. The fourth dummy wiring line region DM4 includes a plurality of fourth dummy wiring lines 5(t), and one end of each fourth dummy wiring line 5(t) is coupled to one end of a linear resistor 3(t) via a fourth capacitor C1(t). Each fourth dummy wiring line 5(t) is coupled only to one end of the linear resistor via a capacitor and is not coupled to the other end. One end of a fourth dummy wiring line 5(t+1) located next to the fourth dummy wiring line 5(t) is coupled to the other end of the linear resistor 3(t) via a fourth capacitor C1(t+1). One end of at least one linear resistor 3(t) is connected to the second output electrode EN. A configuration in which the second output electrode EN is arranged inside the fourth dummy wiring line region DM4 is also possible, but the second output electrode EN does not have to be arranged there. A reference electrode EG is arranged between the third dummy wiring line region DM3 and the fourth dummy wiring line region DM4. The reference electrode EG is connected to one end of at least one linear resistor.

Note that the third dummy wiring line region DM3 and the fourth dummy wiring line region DM4 can also be omitted. However, the resistor is slightly affected by the presence or absence of a surrounding dummy wiring line region. Therefore, to reduce the influence on a measurement result, it is desirable that the resistor chip 10 includes the third dummy wiring line region DM3 and the fourth dummy wiring line region DM4. That is, since the resistor chip 10 of this embodiment is intended for voltage measurement, if dummy wiring line regions are arranged around all of the first resistor RP, the second resistor RN, the first voltage detection resistor RPS, and the second voltage detection resistor RNS, it is considered that the uniformity of factors affecting the voltage measurement increases, and more precise measurement can be performed.

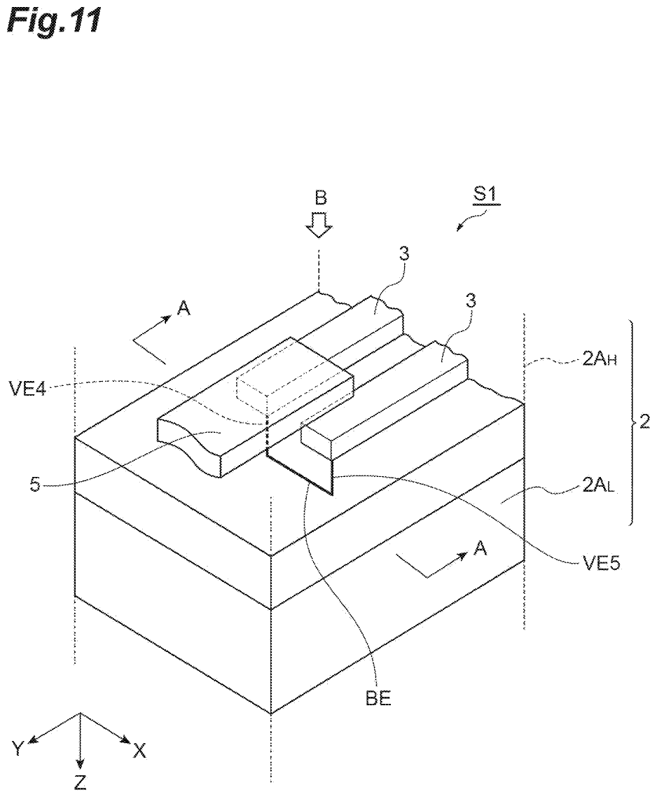

FIG. 11 is a perspective view of a coupling portion indicated by a first region S1 in FIG. 10.

A linear resistor 3 (linear resistor 3(n)) is embedded in the insulating layer 2 , and an adjacent linear resistor 3 is electrically connected via a via electrode and a buried electrode BE (buried electrode BE(n)). That is, one end of a first linear resistor 3 is connected to the buried electrode BE via a fourth via electrode VE4, and one end of an adjacent second linear resistor 3 is connected to the buried electrode BE via a fifth via electrode VE5. One end of the linear resistor 3 is capacitively coupled to one end of a dummy wiring line 5 (first dummy wiring line 5(n)). In other words, a capacitor (parasitic capacitor: see capacitor C1 in FIG. 10) is formed between one end of the linear resistor 3 and one end of the dummy wiring line 5, and a material of the insulating layer 2 (in this example, a material of the first dielectric layer 2A) is interposed between electrodes constituting the capacitor. A structure of a coupling portion in other resistors (the second resistor RN, the first voltage detection resistor RPS, the second voltage detection resistor RNS) is the same as a structure of the coupling portion in the first region S1 in the first resistor RP.

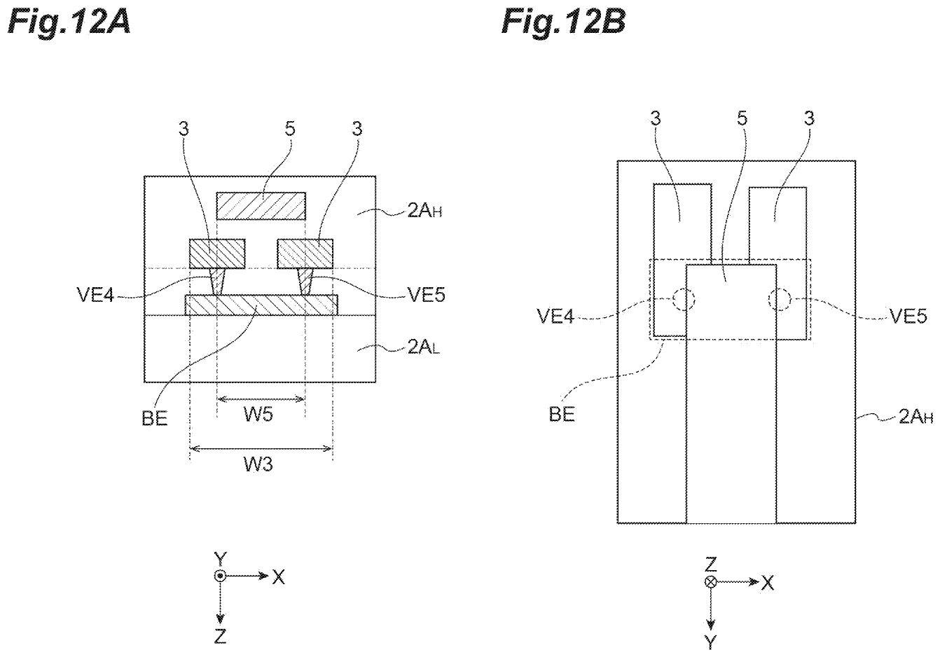

FIG. 12A is a vertical cross-sectional view along line A-A of the coupling portion shown in FIG. 11 and FIG. 12B is a plan view thereof. In the vertical cross-sectional view, illustrations of the region located above the upper dielectric layer 2A_{H} and the region located below the lower dielectric layer 2A_{L} are omitted. In the plan view, a state is shown in which a region located above the linear resistor 3 in the upper dielectric layer 2A_{H} is removed.

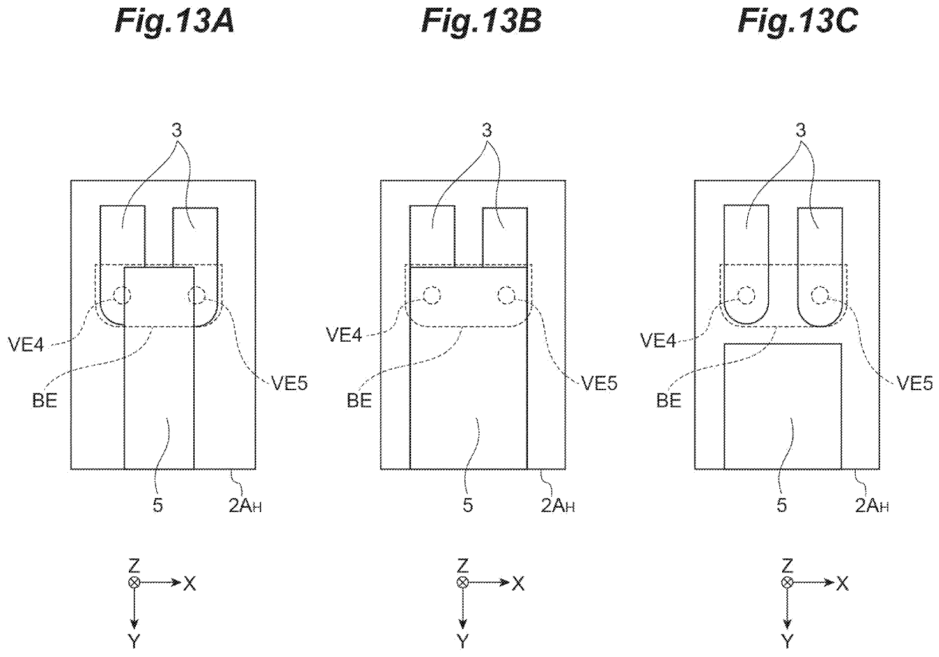

A width W5 in the X-axis direction of one dummy wiring line 5 is smaller than a maximum width W3 in the X-axis direction of a group including two adjacent linear resistors 3. When viewed from the Z-axis direction, an end of one dummy wiring line 5 partially overlaps with ends of the two linear resistors 3 (referred to as a semi-overlapping structure), and the buried electrode BE is located below the dummy wiring line 5. In the case of this semi-overlapping structure, the capacitor becomes smaller than in a fully overlapping structure (FIG. 13B).

FIG. 13A, FIG. 13B, and FIG. 13C are plan views of a modified coupling portion.

In FIG. 13A, a planar shape of a tip portion of the linear resistor 3 shown in FIG. 12B is rounded to have a semicircular shape, and a corner portion of a planar shape of the buried electrode BE is rounded to match this shape. Since there are no right-angled corners, electric field concentration can be relaxed, and breakdown voltage can be increased.

In FIG. 13B, the width in the X-axis direction of the dummy wiring line 5 shown in FIG. 13A is widened, and in a plan view, the width in the X-axis direction of the dummy wiring line 5 is equal to or greater than the maximum width in the X-axis direction of a group including two adjacent linear resistors 3. Since the capacitance of the capacitor depends on the electrode area, the capacitance of the capacitor can be increased, and when the amount of charge stored in the capacitor is the same, the electric field per unit area can be reduced.

In FIG. 13C, linear resistor 3 does not exist directly under the dummy wiring line 5. That is, the overlap ratio between the dummy wiring line 5 and the linear resistor 3 in a plan view is 0%. Even in this case, a parasitic capacitor can be formed between a tip portion of the dummy wiring line 5 and one end of the linear resistor 3. Note that when the distance between the tip portion of the dummy wiring line 5 and one end of the linear resistor 3 becomes large, the parasitic capacitor is not formed, an electrical coupling is released, and an alternating current such as a transient current generated on the first electrode side does not flow to the linear resistor.

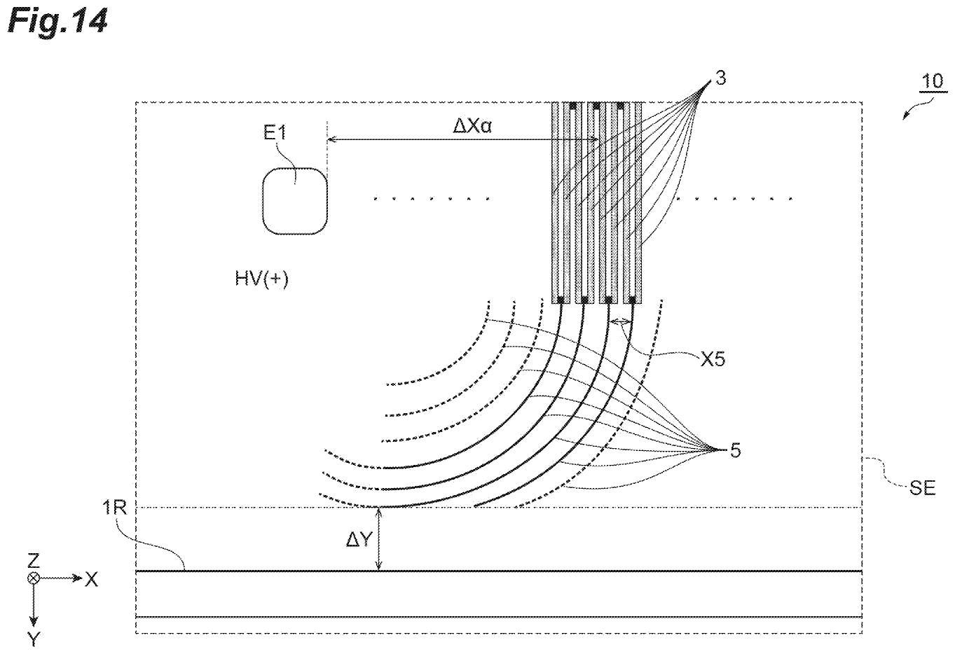

FIG. 14 is a plan view of the dummy wiring line 5 located near a substrate edge and is an enlarged view of an electrode vicinity region SE in FIG. 4.

A plurality of linear resistors 3 is arranged in alignment along the X-axis direction. A dummy wiring line 5 is capacitively coupled to one end of each linear resistor 3. The plurality of dummy wiring lines 5 extends in an annular shape to surround the first electrode E1. A positive first voltage V1 is applied to the first electrode E1 from a first input terminal HV(+). For example, the first voltage V1=5000 V. It is assumed that a specific linear resistor 3 is located at a position of a distance ΔXα in the X-axis direction from the first electrode E1. It is assumed that a voltage Vα of the linear resistor 3 at the distance ΔXα is, for example, a voltage Vα=2500 V. The shortest distance ΔY in the Y-axis direction between the dummy wiring line 5 connected to this specific linear resistor 3 and the ring-shaped conductor 1R is set so that a voltage gradient (Vα/ΔY) in a region defined by ΔY is 100 (V/μm) or less (Vα/ΔY≤100 (V/μm)). By making the voltage gradient smaller than the threshold value, an electric field strength near a substrate side surface of the resistor chip can be reduced, and a breakdown voltage of the resistor chip can be further improved. Since Vα/100 (μm)≤ΔY (μm), it follows that Vα=2500 V, and 25 (μm)≤ΔY (μm).

Note that as a specific instantaneous maximum voltage assumed in an electric vehicle or a hybrid vehicle, 10000 V can be used as Vα. Similarly, a lower limit value of Vα can be assumed to be 500 V. That is, the resistor chip can be designed with 500 V≤Vα≤10000 V. When Vα is in this range, 5 (μm)≤ΔY≤100 (μm) can be satisfied.

The resistor chip 10 includes a ring-shaped conductor 1R that is arranged along a side surface of the semiconductor substrate to surround the resistor in the semiconductor substrate in a plan view and is embedded in the insulating layer. The shortest distance ΔY (μm) between the plurality of dummy wiring lines 5 and the ring-shaped conductor 1R is set to satisfy Vα (V)/100 (V/μm)≤ΔY (μm), where Vα (V) is the magnitude of the voltage between a potential of one of the dummy wiring lines 5 that gives the shortest distance ΔY and a ground potential.

Note that there are structures in which the linear resistor 3 and the dummy wiring line 5 are not connected but are capacitively coupled, and structures in which they are electrically connected. In the case of the electrically connected structure, the potential of the linear resistor 3 becomes equal to the potential of the dummy wiring line, but in the case of the capacitively coupled structure, potentials may be different. Even in such a case, if ΔY satisfies the above-described range when the linear resistor 3 and the dummy wiring line 5 are electrically connected, the electric field strength near the substrate side surface can be lowered and the breakdown voltage of the resistor chip can be increased.

When a resistance value between the first electrode E1 and the linear resistor 3 at the distance ΔXα is R_{TH}, and a resistance value between the first electrode E1 and the reference electrode EG is R_{HALF}, the voltage Vα is given by Vα=V1×((R_{HALF}−R_{TH})/R_{HALF}). In a region indicated by the distance ΔXα, when there are N linear resistors 3, if each resistance value is R, the resistance value R_{TH} is given by R_{TH}=N×R. If the number of dummy wiring lines 5 is N/2 when the number of linear resistors 3 is an even number, the potential difference ΔV5 between adjacent dummy wiring lines 5 can be given by, for example, ΔV5=2×(Vα/N) when these are connected to each linear resistor. In such a case, a distance X5 between adjacent dummy wiring lines 5 can also be set so that ΔV5/X5≤100 (V/μm). There is a structure in which the linear resistor 3 and the dummy wiring line 5 are not connected but are capacitively coupled, and a structure in which they are electrically connected, but it is safe from the viewpoint of increasing the breakdown voltage if the design is made assuming that they are electrically connected.

When the maximum value of Vα is 10000 V and N=100, X5 can be set so that 2 (μm)≤X5. Note that a threshold value of the electric field strength, 100 (V/μm), is set based on a breakdown voltage between wiring lines in an insulating film. Since a breakdown voltage of an exemplary commercially available product is 373 (V/μm), an upper limit threshold of the electric field strength can be set to 100 (V/μm) as described above, considering a margin. When the spacing between the linear resistors is set so as to ensure that the electric field strength is 100 V/μm or less, the distance X5 between adjacent dummy wiring lines (5) can accordingly be set in the range of 0.1 μm≤X5≤5 μm. In addition, although the distance relationships in the peripheral structure of the first electrode E1 have been described above, these relationships can also be applied to the peripheral structure of the second electrode.

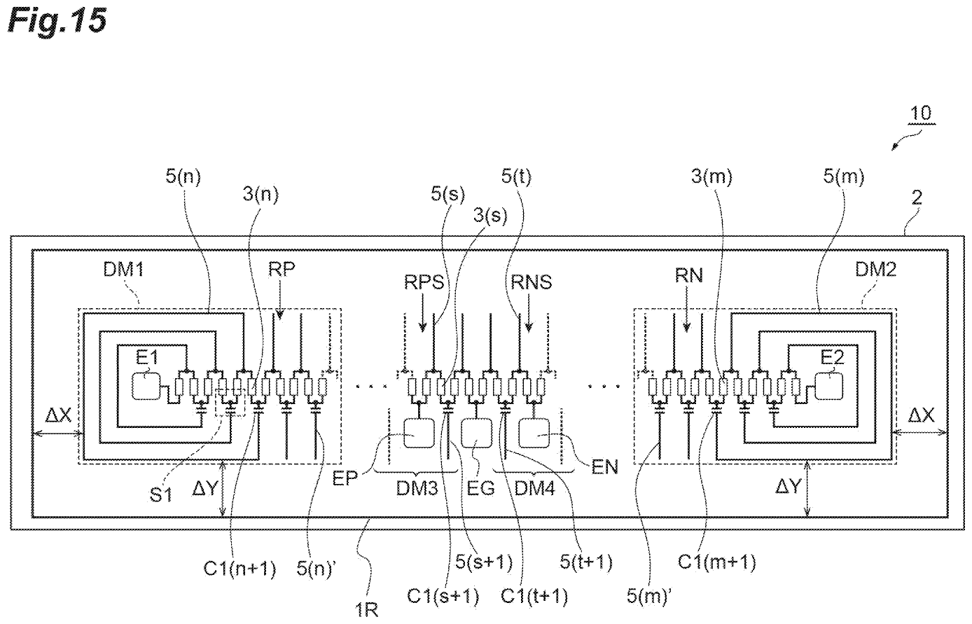

FIG. 15 is a diagram showing a planar configuration for explaining an electrical connection relationship of a voltage divider circuit formed in the resistor chip 10.

This resistor chip 10 differs from the resistor chip 10 shown in FIG. 10 only in that the connectivity of the dummy wiring lines 5 is changed. Specifically, one end of each dummy wiring line 5(n) surrounding the first electrode E1 is electrically connected to one end of the corresponding linear resistor 3(n), while the other ends of these dummy wiring lines 5(n) are not electrically connected to the linear resistors 3(n) but are capacitively coupled thereto. Similarly, one end of each dummy wiring line 5(m) surrounding the second electrode E2 is electrically connected to one end of the corresponding linear resistor 3(m), while the other ends of these dummy wiring lines 5(m) are not electrically connected to the linear resistors 3(m) but are capacitively coupled thereto.

In this example, in the third dummy wiring line region DM3 as well, some of the dummy wiring lines 5(s) have one end electrically connected to one end of the linear resistor 3(s). Likewise, in the fourth dummy wiring line region DM 4, some of the dummy wiring lines 5(t) have one end electrically connected to one end of the linear resistor 3(t).

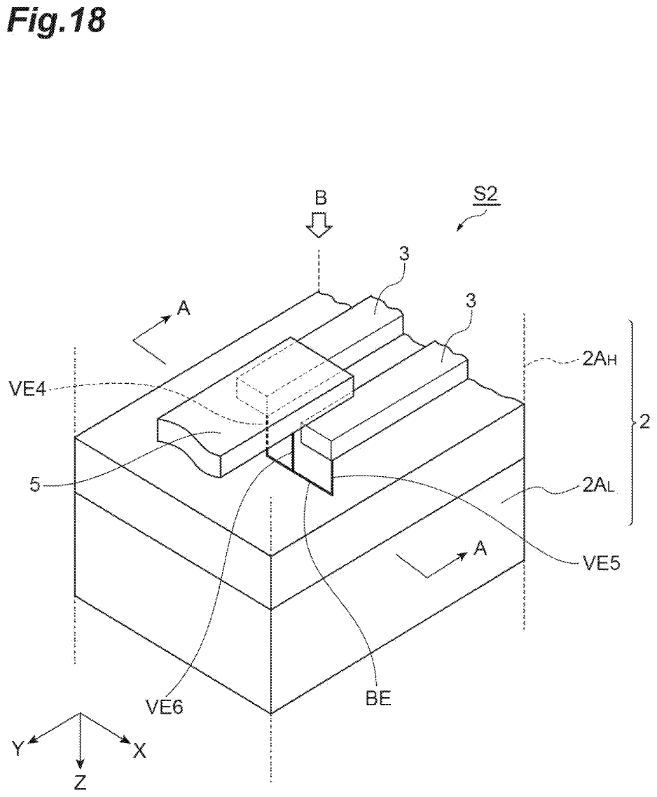

Note that an electrical connection between the dummy wiring line 5 and the linear resistor 3 is made via a via electrode and a buried electrode. That is, a via electrode extending downward from the dummy wiring line 5 is connected to the buried electrode, and the buried electrode is connected to one end of the linear resistor 3 via another via electrode (see FIG. 18).

One end of the dummy wiring line 5 affected by an electric field around the first electrode E1 or the second electrode E2 is connected to the linear resistor 3, but the other end is not connected to the linear resistor 3, so that an influence of a potential difference generated between both ends of the linear resistor 3 can be suppressed. That is, if both ends of the linear resistor 3 where a potential difference occurs are connected, a current flows through the dummy wiring line 5, but in this structure, such a phenomenon does not occur.

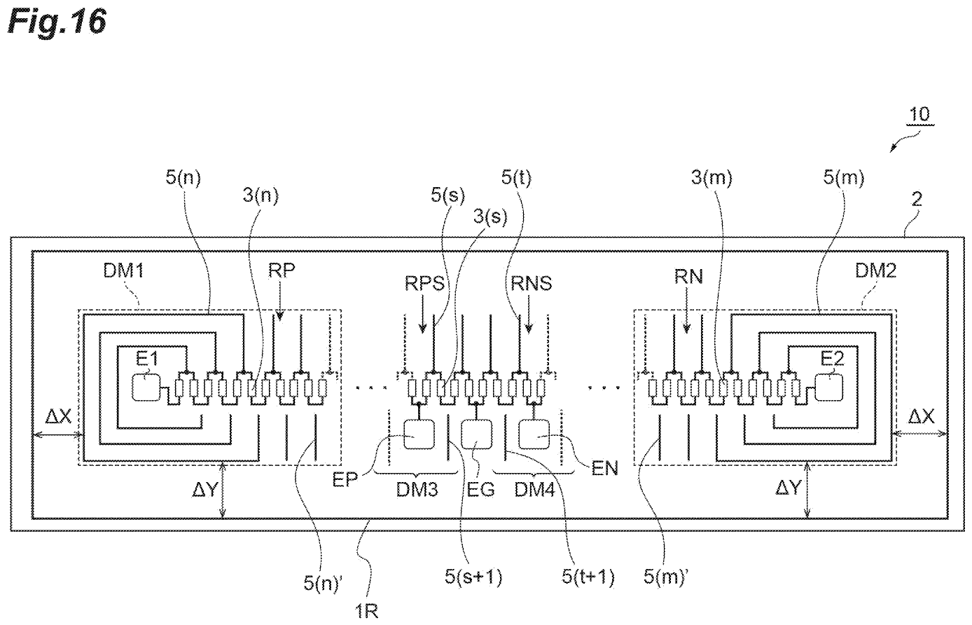

FIG. 16 is a diagram showing a planar configuration for explaining an electrical connection relationship of a voltage divider circuit formed in the resistor chip 10.

This resistor chip 10 is obtained by removing the capacitor C1 from the resistor chip 10 shown in FIG. 15 and releasing a capacitive coupling between the dummy wiring line 5 and the linear resistor 3. In other words, the distance between a tip of the dummy wiring line 5 that was capacitively coupled and the linear resistor 3 is increased so that they are not substantially capacitively coupled.

Even in the case of this structure, one end of the dummy wiring line 5 affected by an electric field around the first electrode E1 or the second electrode E2 is connected to the linear resistor 3, but the other end is not connected to the linear resistor 3, so that an influence of a potential difference generated between both ends of the linear resistor 3 can be suppressed. That is, a current due to a potential difference between both ends of the linear resistor 3 does not flow through the dummy wiring line 5.

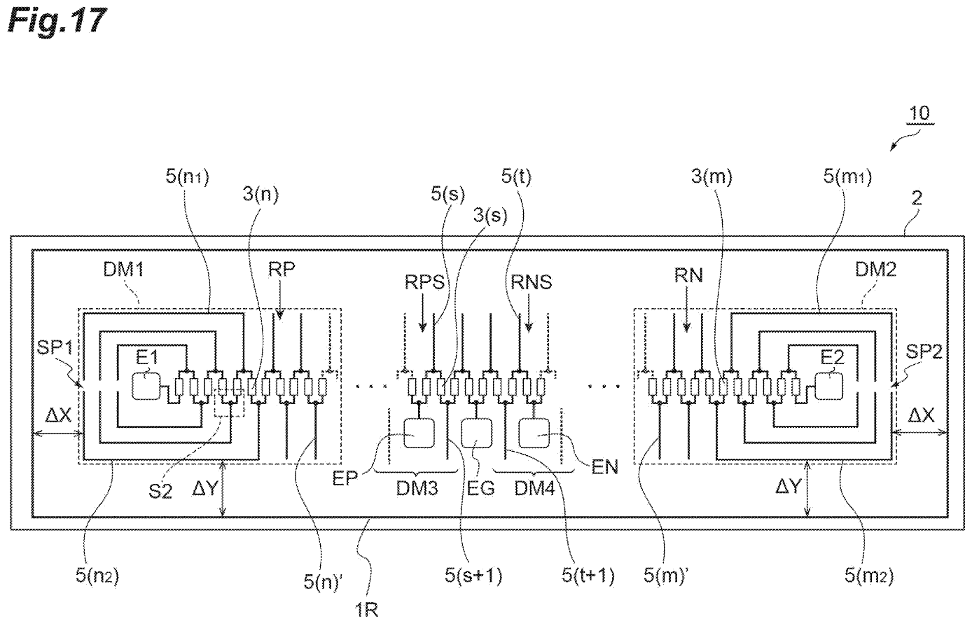

FIG. 17 is a diagram showing a planar configuration for explaining an electrical connection relationship of a voltage divider circuit formed in the resistor chip 10.

This resistor chip 10 is one in which one end of a dummy wiring line 5 (dummy wiring line (5(n), 5(m), 5(s), 5(t))) whose capacitive coupling has been released in the resistor chip 10 shown in FIG. 16 is electrically connected to one end of a linear resistor 3. In this resistor chip 10, furthermore, each dummy wiring line 5(n) surrounding the first electrode E1 is separated by a first space SP 1, and each dummy wiring line 5(m) surrounding the second electrode E2 is separated by a second space SP 2, so that both ends of each linear resistor 3 are not electrically connected by the dummy wiring line 5. The first space SP1 is a set of gaps between the dummy wiring lines 5(n) that face each other and are spaced along the Y-axis direction, and since they are aligned along the X-axis direction, it looks like a slit as a whole. The second space SP2 is also a set of gaps between the dummy wiring lines 5(m) that face each other and are spaced along the Y-axis direction, and since they are aligned along the X-axis direction, it looks like a slit as a whole.

Even in the case of this structure, one end of the dummy wiring line 5 affected by an electric field around the first electrode E1 or the second electrode E2 is connected to the linear resistor 3, but the other end is not connected to the linear resistor 3, so that an influence of a potential difference generated between both ends of the linear resistor 3 can be suppressed.

Specifically, one dummy wiring line 5(n1) in the plurality of first dummy wiring lines 5(n) is electrically connected to a first location of a first linear resistor 3(n) (first resistance layer) in the plurality of linear resistors 3(n) (resistance layers). Another dummy wiring line 5(n2) in the plurality of first dummy wiring lines 5(n) is electrically connected to a second location different from the first location in the plurality of linear resistors 3(n) (resistance layers). An end of the one dummy wiring line 5(n1) opposite the first location and an end of the other dummy wiring line 5(n2) opposite the second location face each other with a gap (first space SP1) therebetween.

Similarly, one dummy wiring line 5(m1) in the plurality of second dummy wiring lines 5(m) is electrically connected to a first location of a first linear resistor 3(m) (first resistance layer) in the plurality of linear resistors 3(m) (resistance layers). Another dummy wiring line 5(m2) in the plurality of second dummy wiring lines 5(m) is electrically connected to a second location different from the first location in the plurality of linear resistors 3(m) (resistance layers). An end of the one dummy wiring line 5(m1) opposite the first location and an end of the other dummy wiring line 5(m2) opposite the second location face each other with a gap (second space SP2) therebetween.

FIG. 18 is a perspective view of a connection portion indicated by a second region S2 in FIG. 17.

A difference between the second region S2 and the first region S1 shown in FIG. 11 is that one end of the linear resistor 3 is electrically connected to one end of the dummy wiring line 5 (first dummy wiring line 5(n)), and other structures are the same as those of the first region S1. That is, one end of a first linear resistor 3 is electrically connected to the buried electrode BE via a fourth via electrode VE4, and one end of an adjacent second linear resistor 3 is electrically connected to the buried electrode BE via a fifth via electrode VE5. The buried electrode BE is connected to one end of the dummy wiring line 5 via a sixth via electrode VE6. A structure of an electrical connection portion in other resistors (the second resistor RN, the first voltage detection resistor RPS, the second voltage detection resistor RNS) is the same as a structure of the electrical connection portion of the second region S2 in the first resistor RP.

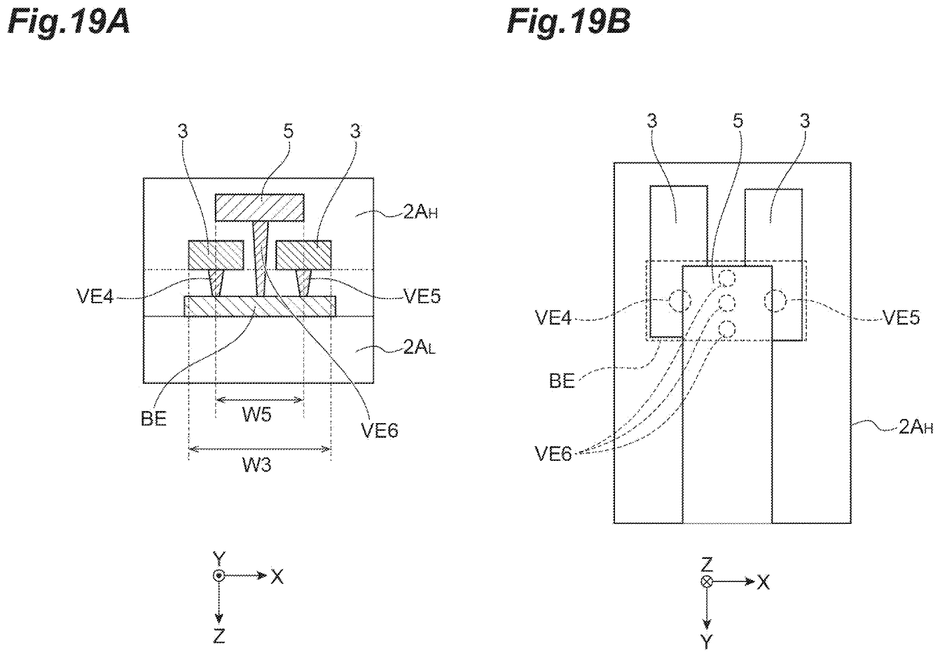

FIG. 19A is a vertical cross-sectional view along line A-A of the connection portion shown in FIG. 18 and FIG. 19B is a plan view thereof.

A structure of the connection portion shown in the figure is a structure in which a sixth via electrode VE6 is added to the structure shown in FIG. 12A and FIG. 12B, and other structures are the same as the structure shown in FIG. 12A and FIG. 12B. The sixth via electrode VE6 connects the buried electrode BE and the dummy wiring line 5. The number of sixth via electrodes VE6 existing at one connection location may be one or more.

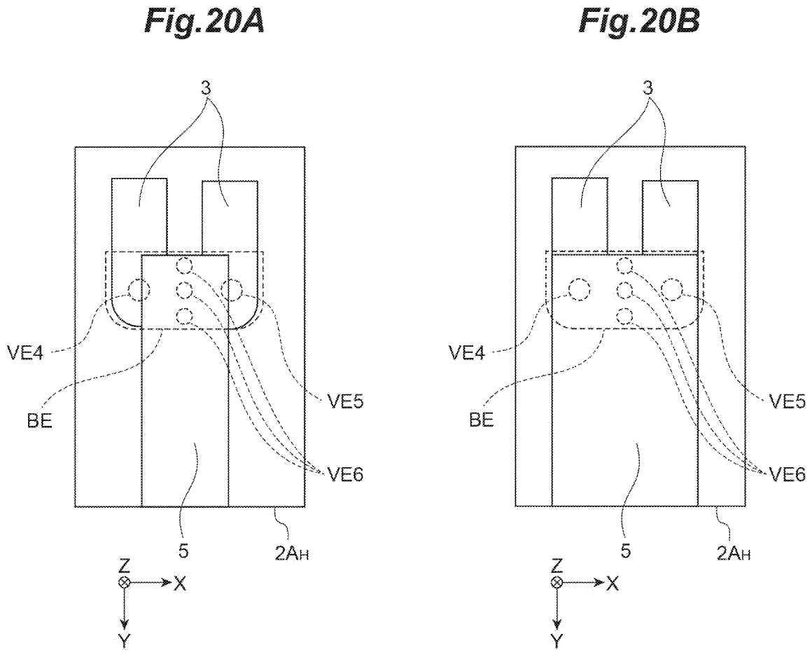

FIG. 20A and FIG. 20B are plan views of a modified connection portion.

Structures of the connection portions shown in FIG. 20A and FIG. 20B are structures in which a sixth via electrode VE6 is added to the structures shown in FIG. 13A and FIG. 13B, and other structures are the same as the structures shown therein. The sixth via electrode VE6 is located in a region of a gap between ends of adjacent linear resistors 3 in a plan view. Since this gap extends along the Y-axis direction, when a plurality of sixth via electrodes VE6 are arranged at one connection location, they can be arranged along the Y-axis direction. Of course, the number of sixth via electrodes VE6 existing at one connection location may be one.

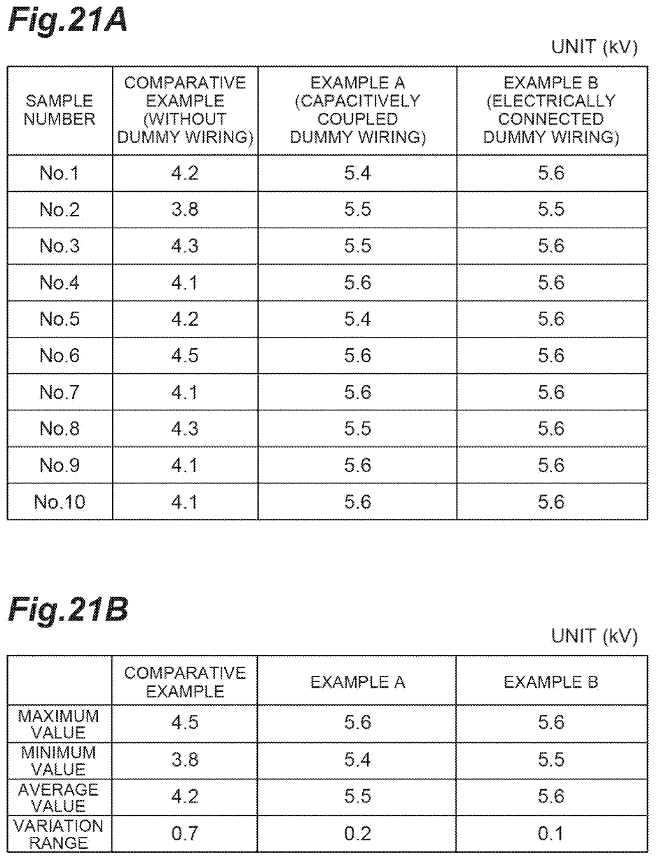

FIG. 21A and FIG. 21B are charts showing a breakdown voltage (kV) obtained with a sample element. When the voltages of the first electrode and the second electrode are increased with the potential of the centrally located reference electrode held at ground potential, breakdown occurs at a certain voltage. The breakdown voltage is defined as the voltage at this point.

Ten samples (sample numbers (No. 1 to No. 10)) of each type of structure of a comparative example, Example A, and Example B were manufactured.

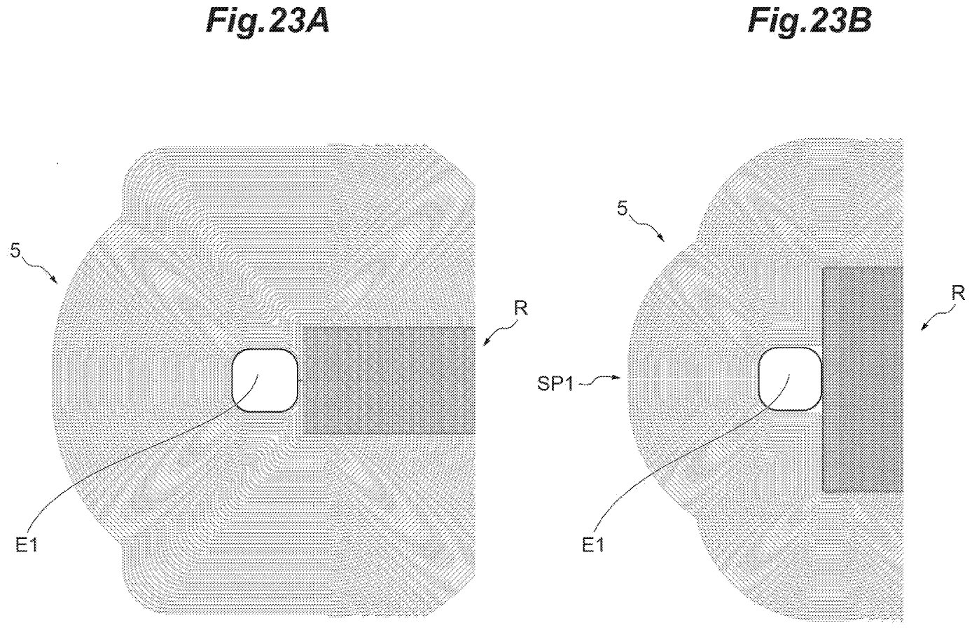

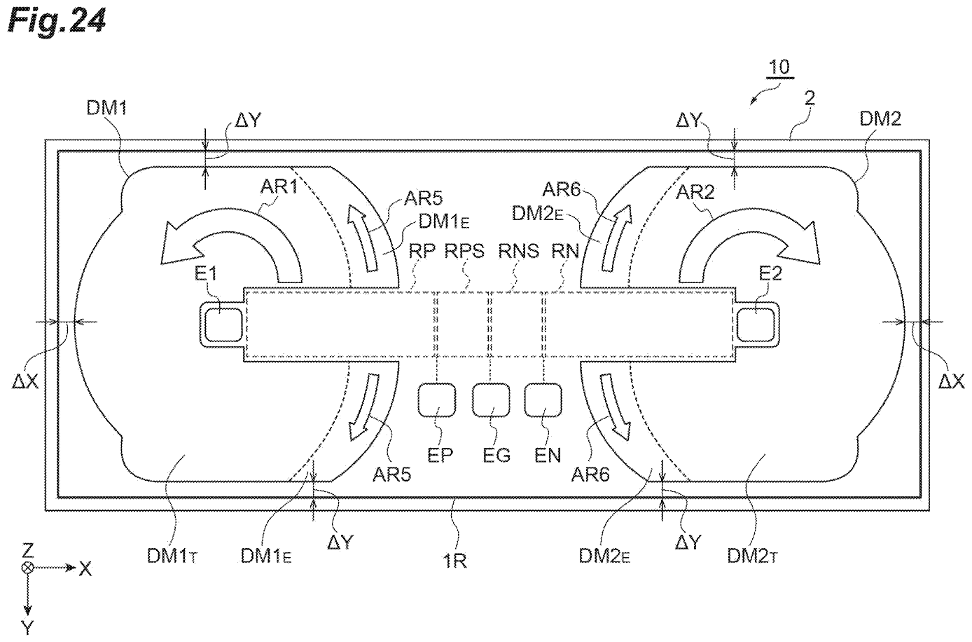

A resistor chip of Example A is a type of resistor chip including capacitively coupled dummy wiring lines, has a capacitively coupled electrical connection relationship shown in FIG. 10, has a resistor array structure as in FIG. 5, and includes a dummy wiring line pattern as in FIG. 23A. The coupling structure of the dummy wiring line and the linear resistor is shown in FIG. 12A and FIG. 12B. A maximum value of a breakdown voltage (kV) of the resistor chip of Example A was 5.6 kV, a minimum value was 5.4 kV, an average value was 5.5 kV, and a variation range (maximum value−minimum value) was 0.2 kV. In Example A, a third dummy wiring line region and a fourth dummy wiring line region are not provided (see FIG. 24).

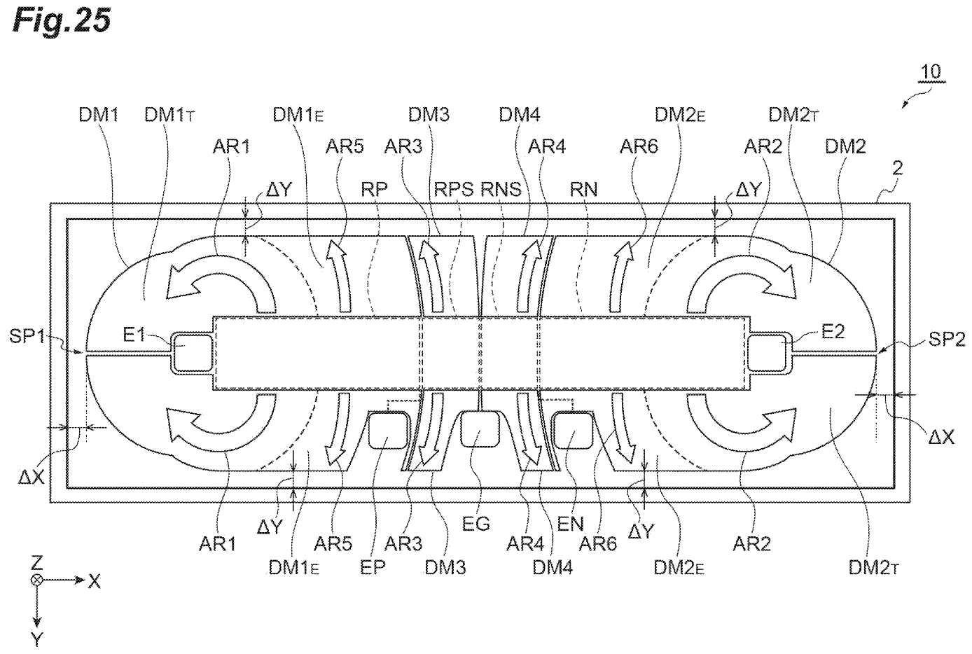

A resistor chip of Example B is a type of resistor chip including electrically connected dummy wiring lines, has an electrically connected electrical connection relationship shown in FIG. 17, has a resistor array structure as in FIG. 5, and includes a dummy wiring line pattern as in FIG. 23B. The coupling structure of the dummy wiring line and the linear resistor is shown in FIG. 19A and FIG. 19B, and an interval between adjacent dummy wiring lines is the same as that of Example A. The maximum value of a breakdown voltage (kV) of the resistor chip of Example B was 5.6 kV, a minimum value was 5.5 kV, an average value was 5.6 kV, and a variation range (maximum value-minimum value) was 0.1 kV. In Example B, a third dummy wiring line region and a fourth dummy wiring line region are provided (see FIG. 25).

A resistor chip of the comparative example is a type of resistor chip not including dummy wiring lines, and has a structure in which the dummy wiring lines are removed from the resistor chip of Example A. The maximum value of the breakdown voltage (kV) of the resistor chip of the comparative example was 4.5 kV; the minimum value was 3.8 kV; the average value was 4.2 kV; and the variation range (maximum value-minimum value) was 0.7 kV.

Data for Example A are superior to those of the comparative example; the maximum and average breakdown voltages are higher, and the variation range is smaller. Data for Example B are also superior to those of the comparative example. The maximum and average breakdown voltages increase, and the variation range decreases. When the resistor chip was destroyed by applying a high voltage exceeding the upper-limit value, damage traces were observed along the width (Y-axis) direction in the comparative example (without dummy wiring lines). By contrast, in structures incorporating dummy wiring lines as in Examples A and B, damage traces were observed along the longitudinal (X-axis) direction of the resistor chip. Without being bound by theory, it is believed that one factor contributing to the increase in breakdown voltage due to the provision of the plurality of dummy wiring lines is that an electric field strength distribution around the first and second electrodes becomes more gradual. That is, in this embodiment, by arranging the dummy wiring lines around the resistor element, the electric field is relaxed, and the breakdown voltage is improved. The plurality of dummy wiring lines is arranged in a stripe-like pattern in a direction away from the first and second electrodes, and a change in the electric field strength along the direction away from the electrodes becomes gentle. In addition, a component such as a transient current can also flow into a linear resistor closer to ground potential.

In this example, the data of Example B are superior to those of Example A from the viewpoint of the variation range, but the difference is within the margin of error, and both exhibit excellent effects.

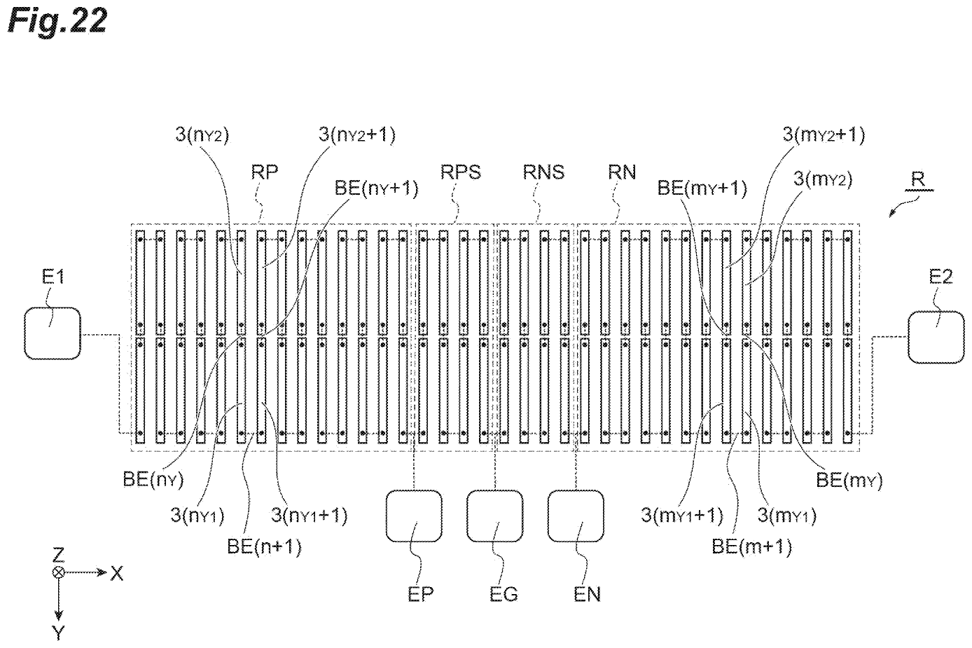

FIG. 22 is a plan view of a modified structure of a voltage divider circuit portion in a resistor chip.

In the planar structure shown in FIG. 5, single linear resistors 3 extending along the Y-axis direction were arranged in alignment along the X-axis direction. On the other hand, in this example, a plurality of (two) linear resistors 3 is arranged along the Y-axis direction, and groups of linear resistors are arranged in alignment along the X-axis direction.

The first resistor RP includes a linear resistor 3(n_{Y1}) and a linear resistor 3(n_{Y2}) aligned along the Y-axis direction at an arbitrary X coordinate. These linear resistor 3(n_{Y1}) and linear resistor 3(n_{Y2}) are electrically connected via the via electrode and the buried electrode BE(n_{Y}) as described above. One end of the linear resistor 3(n_{Y1}) is electrically connected to an adjacent linear resistor 3(n_{Y1+1}) in the X-axis direction via a via electrode and a buried electrode BE(n+1). The linear resistor 3(n_{Y1+1}) is electrically connected to a linear resistor 3(n_{Y2+1}) aligned along the Y-axis direction via a via electrode and a buried electrode BE(n_{Y+1}).

The second resistor RN includes a linear resistor 3(m_{Y1}) and a linear resistor 3(m_{Y2}) aligned along the Y-axis direction at an arbitrary X coordinate. The linear resistor 3(m_{Y1}) and linear resistor 3(m_{Y2}) are electrically connected via the via electrode and the buried electrode BE(mY) as described above. One end of the linear resistor 3(m_{Y1}) is connected to an adjacent linear resistor 3(mY1+1) in the X-axis direction via a via electrode and a buried electrode BE(m+1). The linear resistor 3(m_{Y1+1}) is electrically connected to a linear resistor 3(m_{Y2+1}) aligned along the Y-axis direction via a via electrode and a buried electrode BE(m_{Y+1}).

FIG. 23A is a plan view of capacitively coupled dummy wiring lines near a first electrode and FIG. 23B is a plan view of electrically connected dummy wiring lines near the first electrode.

The capacitively coupled dummy wiring line 5 (FIG. 23A) is capacitively coupled to the resistor R and surrounds the first electrode E1. The planar shape of the first electrode E1 is a quadrangle, but its corners are rounded, and the dummy wiring line 5 draws an arc along an outer edge of the first electrode E1.

The electrically connected dummy wiring line 5 (FIG. 23B) is electrically connected to the resistor R and surrounds the first electrode E1. The planar shape of the first electrode E1 is a quadrangle, but its corners are rounded, and the dummy wiring line 5 draws an arc along an outer edge of the first electrode E1. In a region of the first electrode E1 opposite to the resistor R, a slit (first space SP1) is formed between the dummy wiring lines 5.

Note that a structure on a second electrode side is the same as a structure on a first electrode side.

FIG. 24 is a plan view of a resistor chip including capacitively coupled dummy wiring lines. Since each element is embedded in the insulating layer 2 , an insulating layer located on the necessary elements is omitted.

A first dummy wiring line region DM1 includes a dummy wiring line group capacitively coupled to a first resistor RP. Overall, the first resistor RP extends along the X-axis direction. At a capacitive coupling position between the dummy wiring line and the first resistor RP, the dummy wiring line extends along the Y-axis direction. That is, at the capacitive coupling position, a longitudinal direction of the first resistor RP and a direction in which each dummy wiring line extends are orthogonal to each other.

The first dummy wiring line region DM1 includes a first electrode side region DM1_{T} and a first output electrode side region DM1_{E}. An example of an actual dummy wiring line arranged in the first dummy wiring line region DM1 is as shown in FIG. 23A.

The first electrode side region DM1_{T} is composed of a dummy wiring line group surrounding the first electrode E1. The dummy wiring line group extends to surround the first electrode E1 along a first arrow AR1. Among the dummy wiring lines surrounding the first electrode E1, there is a gap between a dummy wiring line located at an outermost periphery and the ring-shaped conductor 1R, and the shortest distance thereof along the Y-axis direction is the above described ΔY. There is a gap between the dummy wiring line located at this outermost periphery and the ring-shaped conductor 1R, and the shortest distance ΔX thereof along the X-axis direction can be set so that ΔX=ΔY.

The first output electrode side region DM1_{E} is composed of a dummy wiring line group that does not surround the first electrode E1. The dummy wiring line group extends along a fifth arrow AR5 to be separated from the first resistor RP and approaches the ring-shaped conductor 1R, and there is a gap along the Y-axis direction between a tip portion thereof and the ring-shaped conductor 1R, and the shortest distance thereof along the Y-axis direction is the above described ΔY.

A second dummy wiring line region DM2 includes a dummy wiring line group capacitively coupled to a second resistor RN. Overall, the second resistor RN extends along the X-axis direction. At the capacitive coupling positions between the dummy wiring lines and the second resistor RN, the respective dummy wiring line extends along the Y-axis direction. That is, at the capacitive coupling positions, the longitudinal direction of the second resistor RN and the direction in which each dummy wiring line extends are orthogonal to each other.

The second dummy wiring line region DM2 includes a second electrode side region DM2_{T} and a second output electrode side region DM2_{E}. An example of an actual dummy wiring line arranged in the second dummy wiring line region DM2 is the same as a plane-symmetrical structure with respect to the YZ plane of the structure of FIG. 23A.

The second electrode side region DM2_{T} is composed of a dummy wiring line group surrounding the second electrode E2. The dummy wiring line group extends to surround the second electrode E2 along a second arrow AR2. Among the dummy wiring lines surrounding the second electrode E2, there is a gap between a dummy wiring line located at an outermost periphery and the ring-shaped conductor 1R, and the shortest distance thereof along the Y-axis direction is the above described ΔY. There is a gap between the dummy wiring line located at the outermost periphery and the ring-shaped conductor 1R, and the shortest distance ΔX thereof along the X-axis direction can be set so that ΔX=ΔY.

The second output electrode side region DM2_{E} is composed of a dummy wiring line group that does not surround the second electrode E2. The dummy wiring line group extends along a sixth arrow AR6 to be separated from the second resistor RN and approaches the ring-shaped conductor 1R, and there is a gap along the Y-axis direction between a tip portion thereof and the ring-shaped conductor 1R, and the shortest distance thereof along the Y-axis direction is the above described ΔY.

FIG. 25 is a plan view of a resistor chip including electrically connected dummy wiring lines. Since each element is embedded in the insulating layer 2, an insulating layer located on necessary elements is omitted.

A first dummy wiring line region DM1 includes a dummy wiring line group electrically connected to a first resistor RP. Overall, the first resistor RP extends along the X-axis direction. At an electrical connection position between the dummy wiring line and the first resistor RP, the dummy wiring line extends along the Y-axis direction. That is, at the electrical connection position, a longitudinal direction of the first resistor RP and a direction in which each dummy wiring line extends are orthogonal to each other.

The first dummy wiring line region DM1 includes a first electrode side region DM1_{T} and a first output electrode side region DM1_{E}. An example of an actual dummy wiring line arranged in the first dummy wiring line region DM1 is as shown in FIG. 23B.

The first electrode side region DM1_{T} is composed of a dummy wiring line group surrounding the first electrode E1. The dummy wiring line group extends to surround the first electrode E1 along a first arrow AR1, but it is divided by a first space SP1 in a region of the first electrode E1 opposite to the first resistor RP. Among the dummy wiring lines extending to the position of the first space SP1, there is a gap between a dummy wiring line located at an outermost periphery and the ring-shaped conductor 1R, and the shortest distance thereof along the Y-axis direction is the above described ΔY. There is a gap between the dummy wiring line located at this outermost periphery and the ring-shaped conductor 1R, and the shortest distance ΔX thereof along the X-axis direction can be set so that ΔX=ΔY.

The first output electrode side region DM1_{E} is composed of a dummy wiring line group that does not surround the first electrode E1 and does not reach the first space SP1. The dummy wiring line group extends along a fifth arrow AR5 to be separated from the first resistor RP and approaches the ring-shaped conductor 1R, and there is a gap along the Y-axis direction between a tip portion thereof and the ring-shaped conductor 1R, and the shortest distance thereof along the Y-axis direction is the above described ΔY.

Note that, in this example, some of the dummy wiring lines in the first output electrode side region DM1_{E} are also arranged around the first output electrode EP.

A second dummy wiring line region DM2 includes a dummy wiring line group electrically connected to a second resistor RN. Overall, the second resistor RN extends along the X-axis direction. At an electrical connection position between the dummy wiring line and the second resistor RN, the dummy wiring line extends along the Y-axis direction. That is, at the electrical connection position, a longitudinal direction of the second resistor RN and a direction in which each dummy wiring line extends are orthogonal to each other.

The second dummy wiring line region DM2 includes a second electrode side region DM2_{T} and a second output electrode side region DM2_{E}. An example of an actual dummy wiring line arranged in the second dummy wiring line region DM2 is the same as a plane-symmetrical structure with respect to a YZ plane of the structure of FIG. 23B.

The second electrode side region DM2_{T} is composed of a dummy wiring line group surrounding the second electrode E2. The dummy wiring line group extends so as to surround the second electrode E2 along a second arrow AR2, but it is divided by a second space SP2 in a region of the second electrode E2 opposite to the second resistor RN. Among the dummy wiring lines extending to the position of the second space SP2, there is a gap between a dummy wiring line located at an outermost periphery and the ring-shaped conductor 1R, and the shortest distance thereof along the Y-axis direction is the above described ΔY. There is a gap between the dummy wiring line located at this outermost periphery and the ring-shaped conductor 1R, and the shortest distance ΔX thereof along the X-axis direction can be set so that ΔX=ΔY.

The second output electrode side region DM2_{E} is composed of a dummy wiring line group that does not surround the second electrode E2 and does not reach the second space SP2. The dummy wiring line group extends along a sixth arrow AR6 to be separated from the second resistor RN and approaches the ring-shaped conductor 1R, and there is a gap along the Y-axis direction between a tip portion thereof and the ring-shaped conductor 1R, and the shortest distance thereof along the Y-axis direction is the above described ΔY.

Note that, in this example, some of the dummy wiring lines in the second output electrode side region DM2_{E} are also arranged around the second output electrode EN.

A third dummy wiring line region DM3 includes a dummy wiring line group electrically connected to a first voltage detection resistor RPS. At an electrical connection position between the dummy wiring line and the first voltage detection resistor RPS, the dummy wiring line extends along the Y-axis direction.

A dummy wiring line group included in the third dummy wiring line region DM3 extends along a third arrow AR3 so as to be separated from the first voltage detection resistor RPS and approaches the ring-shaped conductor 1R, and there is a gap along the Y-axis direction between a tip portion thereof and the ring-shaped conductor 1R, and the shortest distance thereof along the Y-axis direction is the above-described ΔY.

A fourth dummy wiring line region DM4 includes a dummy wiring line group electrically connected to a second voltage detection resistor RNS. At an electrical connection position between the dummy wiring line and the second voltage detection resistor RNS, the dummy wiring line extends along the Y-axis direction.

A dummy wiring line group included in the fourth dummy wiring line region DM4 extends along a fourth arrow AR4 so as to be separated from the second voltage detection resistor RNS and approaches the ring-shaped conductor 1R, and there is a gap along the Y-axis direction between a tip portion thereof and the ring-shaped conductor 1R, and the shortest distance thereof along the Y-axis direction is the above-described ΔY.

Note that the third and fourth dummy wiring line regions can also be provided in a resistor chip of a type as shown in FIG. 24. The number of dummy wiring lines surrounding the electrode can be, for example, about K (e.g., K=6). In other words, the number of dummy wiring lines coupled or connected to one long side (X-axis) of a rectangular resistor included in the first electrode side region DM1_{T} or the second electrode side region DM2_{T} is K, and K may be set such that 3≤K≤30. In addition, the length of the dummy wiring line may be shortened as it approaches the reference electrode EG from the first electrode E1 or the second electrode E2. The reference electrode EG can also have ground potential. When depth positions of the dummy wiring line and the linear resistor are different, a configuration in which the dummy wiring line and the linear resistor overlap over the entire length direction (Y-axis direction) of the linear resistor in a plan view can be considered, but from the viewpoint of breakdown voltage, it is considered that a smaller overlap ratio thereof is preferable (e.g., an overlap ratio along the Y-axis direction is 10% or less).

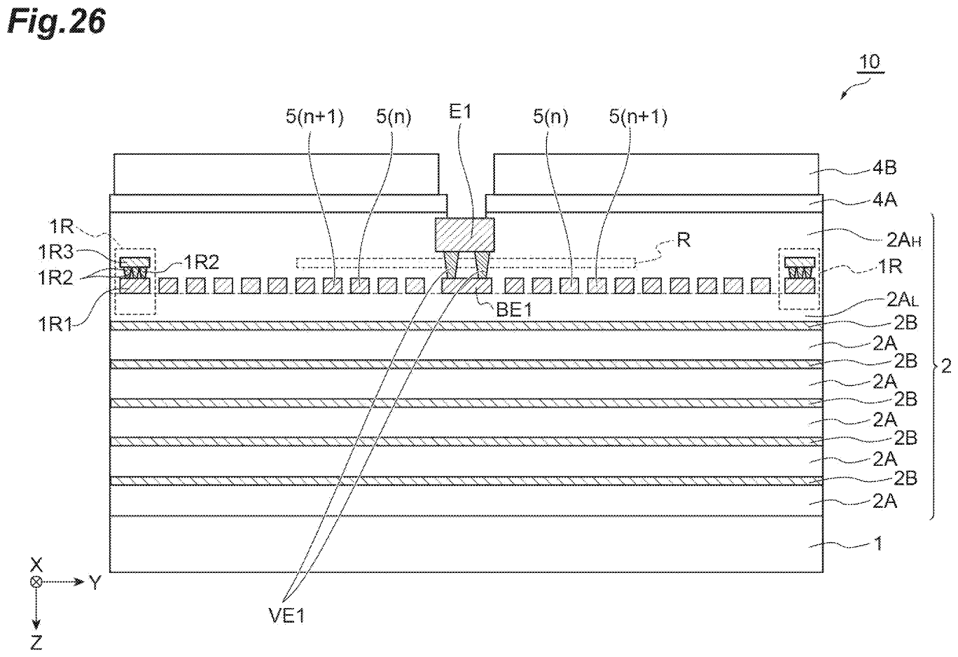

FIG. 26 is a diagram showing a vertical sectional configuration (first modification) of a portion along line A-A in FIG. 4.

The resistor chip 10 of this example has a structure in which a depth position of the first dummy wiring line 5(n) is moved to the same depth position as the first buried electrode BE1 in the resistor chip 10 shown in FIG. 6, and other aspects are the same as those of the structure shown in FIG. 6. In other words, the peripheral electrode 1R1, the first buried electrode BE1, and the first dummy wiring line 5(n) are formed on a surface of the lower dielectric layer 2 AL located in an upper part of the insulating layer 2. In this structure, there is an advantage that the peripheral electrode 1R1, the first buried electrode BE1, and the first dummy wiring line 5(n) can be formed by the same process (a manufacturing method such as a sputtering method, a vapor deposition method, or a plating method).

Each linear resistor constituting the resistor R and the first dummy wiring line 5(n) are capacitively coupled or electrically connected. In the case of capacitive coupling, a tip portion of the first dummy wiring line 5(n) may be positioned in the vicinity of one end of the linear resistor. For electrical connection, one end of the linear resistor may be connected, through a via electrode, to an end portion of the underlying first dummy wiring line 5(n). Although the figure shows a structure on the first electrode E1 side, a structure on the second electrode side is the same as the structure on the first electrode E1 side.

The first modification is a structure in which, as in FIG. 26, each dummy wiring line in FIGS. 7, 8, and 9 is repositioned to the depth of the buried electrode; the respective vertical sectional configurations correspond to those of the portions along lines B-B, C-C, and D-D in FIG. 4.

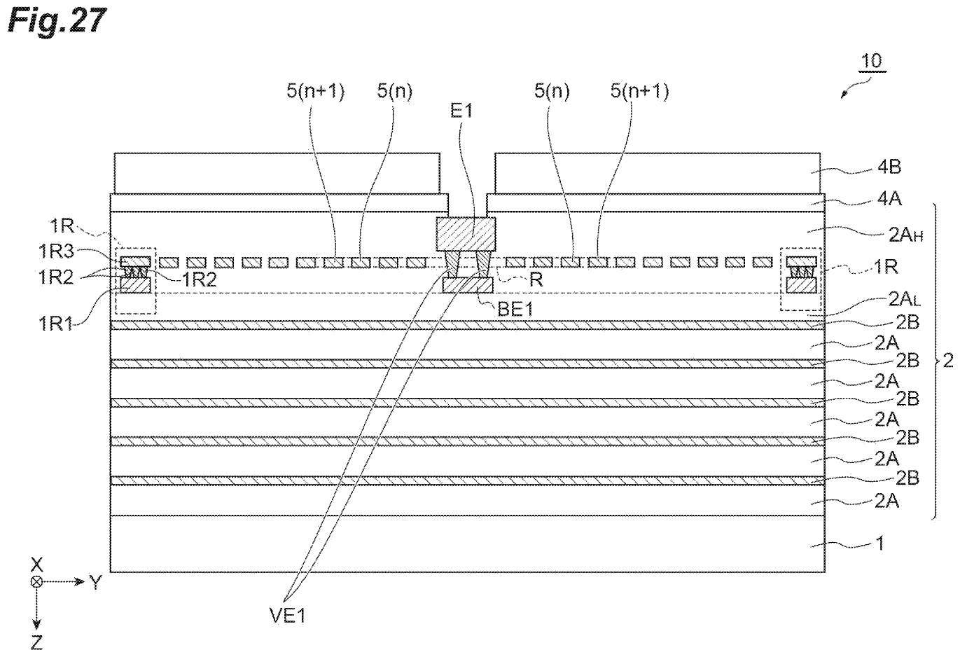

FIG. 27 is a diagram showing a vertical sectional configuration (second modification) of a portion along line A-A in FIG. 4.

The resistor chip 10 in this example differs from the chip shown in FIG. 6 in that the material of the first dummy wiring line 5(n) is changed from a conductor such as a metal to a resistive material, which serves as a dummy resistance layer. Otherwise, the structure is the same as in FIG. 6. The dummy resistance layer does not contribute to the resistance of resistor R. It is believed that multiple dummy resistance layers mitigate the electric field around an electrode under high voltage and function similarly to the dummy wiring lines.

The second modification is a structure in which, as shown in FIG. 27, each dummy wiring line in FIG. 7, FIG. 8, and FIG. 9 is replaced with a dummy resistance layer; the respective vertical sectional configurations correspond to those of portions along lines B-B, C-C, and D-D in FIG. 4.

(Additional Note) As described above, in the above-described resistor chip 10 (semiconductor device), providing the dummy wiring line, the withstand voltage of the resistor chip 10 can be increased. Various embodiments in the present disclosure can be defined as the following additional notes [A1] to [A18].

[A1] A semiconductor device, comprising: a semiconductor substrate 1; an insulating layer 2 provided on the semiconductor substrate 1; a resistor R embedded in the insulating layer 2 and formed by electrically connecting a plurality of resistance layers (linear resistors 3); a first electrode E1 connected electrically to a first end of the resistor R; a second electrode E2 connected electrically to a second end of the resistor R; and a plurality of first dummy wiring lines 5(n) arranged around the first electrode E1 and respectively coupled capacitively to a plurality of resistance layers (linear resistors 3(n)) in the resistor R.

[A2] The semiconductor device according to A1, wherein the resistor R comprises: a first resistor RP connected electrically to the first electrode E1; a second resistor RN connected electrically to the second electrode E2; and a voltage detection resistor (RPS, RNS) that electrically connects the first resistor RP and the second resistor RN and has a resistance value lower than both the first resistor RP and the second resistor RN, and wherein the semiconductor device comprises a first output electrode EP, a second output electrode EN, and a reference electrode EG, which are respectively connected electrically to different locations of the voltage detection resistor (RPS, RNS).

[A3] The semiconductor device according to A2, further comprising a plurality of second dummy wiring lines 5(m) arranged around the second electrode E2 and respectively coupled capacitively to a plurality of resistance layers (linear resistors 3(m)) in the second resistor RN, wherein the plurality of first dummy wiring lines 5(n) are respectively coupled capacitively to a plurality of resistance layers (linear resistors 3(n)) in the first resistor RP.

[A4] The semiconductor device according to A3, wherein the voltage detection resistor comprises: a first voltage detection resistor RPS connected electrically to the first resistor RP and having a resistance value lower than the first resistor RP; and a second voltage detection resistor RNS connected electrically between the second resistor RN and the first voltage detection resistor RPS and having a resistance value lower than the second resistor RN, and wherein the semiconductor device comprises: a plurality of third dummy wiring lines 5(s) respectively coupled capacitively to a plurality of resistance layers (linear resistors 3) in the first voltage detection resistor RPS; and a plurality of fourth dummy wiring lines 5(t) respectively coupled capacitively to a plurality of resistance layers (linear resistors 3) in the second voltage detection resistor RNS.

[A5] The semiconductor device according to any one of A1 to A4, comprising a plurality of first dummy resistance layers (5(n): FIG. 27) instead of the plurality of first dummy wiring lines 5(n).

[A6] A semiconductor device, comprising: a semiconductor substrate 1; an insulating layer 2 provided on the semiconductor substrate 1; a resistor R embedded in the insulating layer 2 and formed by electrically connecting a plurality of resistance layers (linear resistors 3); a first electrode E1 connected electrically to a first end of the resistor R; a second electrode E2 connected electrically to a second end of the resistor R; and a plurality of first dummy wiring lines 5(n) arranged around the first electrode E1 and connected electrically to a plurality of resistance layers (linear resistors 3(n)) in the resistor R.

[A7] The semiconductor device according to A6, wherein one dummy wiring line 5(n1) of the plurality of first dummy wiring lines 5(n) is connected electrically to a first location of a first resistance layer (linear resistor 3(n)) among the plurality of resistance layers (linear resistors 3(n)), wherein another dummy wiring line 5(n2) of the plurality of first dummy wiring lines 5(n) is connected electrically to a second location different from the first location among the plurality of resistance layers (linear resistors 3(n)), and wherein an end of the one dummy wiring line 5(n1) opposite the first location and an end of the other dummy wiring line 5(n2) opposite the second location face each other with a gap (first space SP1) therebetween.

[A8] The semiconductor device according to A6 or A7, wherein the resistor R comprises: a first resistor RP connected electrically to the first electrode E1; a second resistor RN connected electrically to the second electrode E2; and a voltage detection resistor (RPS, RNS) that electrically connects the first resistor RP and the second resistor RN and has a resistance value lower than both the first resistor RP and the second resistor RN, and wherein the semiconductor device comprises a first output electrode EP, a second output electrode EN, and a reference electrode EG, which are connected electrically to different locations of the voltage detection resistor (RPS, RNS).

[A9] The semiconductor device according to A8, further comprising a plurality of second dummy wiring lines 5(m) arranged around the second electrode E2 and connected electrically to a plurality of resistance layers (linear resistors 3(m)) in the second resistor RN, respectively, wherein the plurality of first dummy wiring lines 5(n) are respectively connected electrically to a plurality of resistance layers (linear resistors 3(n)) in the first resistor RP.

[A10] The semiconductor device according to A9, wherein the voltage detection resistor comprises: a first voltage detection resistor RPS connected electrically to the first resistor RP and having a resistance value lower than the first resistor RP; and a second voltage detection resistor RNS connected electrically between the second resistor RN and the first voltage detection resistor RPS and having a resistance value lower than the second resistor RN, and wherein the semiconductor device comprises: a plurality of third dummy wiring lines respectively connected electrically to a plurality of resistance layers (linear resistors 3(s)) in the first voltage detection resistor RPS; and a plurality of fourth dummy wiring lines respectively connected electrically to a plurality of resistance layers (linear resistors 3) in the second voltage detection resistor RNS.

[A11] The semiconductor device according to any one of A6 to A10, comprising a plurality of first dummy resistance layers (5(n): FIG. 27) instead of the plurality of first dummy wiring lines 5(n).

[A12] The semiconductor device according to any one of A1 to A11, wherein a resistance value between the first electrode E1 and the second electrode E2 is 1 MΩ or more and 1000 MΩ or less.

[A13] The semiconductor device according to any one of A1 to A12, wherein a material of the resistance layers constituting the resistor R includes at least one metal compound selected from the group consisting of CrSi, CrSiN, CrSiO, TaN, and TiN.

[A14] The semiconductor device according to any one of A1 to A13, wherein a material of the first dummy wiring lines 5(n) includes Al, Cu, W, or Ti.

[A15] The semiconductor device according to any one of A1 to A14, further comprising a ring-shaped conductor arranged to surround the resistor in a plan view and embedded in the insulating layer, wherein the shortest distance ΔY (μm) between the plurality of first dummy wiring lines and the ring-shaped conductor is set to satisfy Vα (V)/100 (V/μm)≤ΔY (μm), where Vα (V) is the magnitude of the voltage between a potential of one of the first dummy wiring lines that gives the shortest distance ΔY and a ground potential.

[A16] The semiconductor device according to A15, wherein the shortest distance ΔY (μm) satisfies 5 (μm)≤ΔY≤100 (μm).

The resistor chip can also have the semiconductor substrate removed, and an insulating substrate or a conductor substrate can be used instead of the semiconductor substrate.

[A17] A resistor chip, comprising: a resistor R embedded in an insulating layer 2 and formed by electrically connecting a plurality of resistance layers (linear resistors 3); a first electrode E1 connected electrically to a first end of the resistor R; a second electrode E2 connected electrically to a second end of the resistor R; and a plurality of first dummy wiring lines 5(n) arranged around the first electrode E1 and respectively coupled capacitively to a plurality of resistance layers (linear resistors 3) in the resistor R.

[A18] A resistor chip, comprising: a resistor R embedded in an insulating layer 2 and formed by electrically connecting a plurality of resistance layers (linear resistors 3); a first electrode E1 connected electrically to a first end of the resistor R; a second electrode E2 connected electrically to a second end of the resistor R; and a plurality of first dummy wiring lines 5(n) arranged around the first electrode E1 and respectively connected electrically to a plurality of resistance layers (linear resistors 3) in the resistor R.

Various modifications to the above-described embodiments will be readily apparent to those skilled in the art, and the principles described herein may be applied to other embodiments. Various features of the described embodiments may be combined. Individual features may be included in different claims, and such features may be combined in any suitable manner. The embodiments are illustrative and not limiting. The scope is defined by the appended claims.

What is claimed is:

1. A semiconductor device, comprising:
a semiconductor substrate;
an insulating layer provided on the semiconductor substrate;
a resistor embedded in the insulating layer and formed by electrically connecting a plurality of resistance layers;
a first electrode connected electrically to a first end of the resistor;
a second electrode connected electrically to a second end of the resistor; and
a plurality of first dummy wiring lines arranged around the first electrode and respectively coupled capacitively to the plurality of resistance layers in the resistor.

2. The semiconductor device according to claim 1,
wherein the resistor comprises:
a first resistor connected electrically to the first electrode;
a second resistor connected electrically to the second electrode; and
a voltage detection resistor that electrically connects the first resistor and the second resistor and has a resistance value lower than both the first resistor and the second resistor, and
wherein the semiconductor device comprises a first output electrode, a second output electrode, and a reference electrode, which are respectively connected electrically to different locations of the voltage detection resistor.

3. The semiconductor device according to claim 2, further comprising:
a plurality of second dummy wiring lines arranged around the second electrode and respectively coupled capacitively to the plurality of resistance layers in the second resistor,
wherein the first dummy wiring lines are respectively coupled capacitively to the resistance layers in the first resistor.

4. The semiconductor device according to claim 3, wherein the voltage detection resistor comprises:
a first voltage detection resistor connected electrically to the first resistor and having a resistance value lower than the first resistor; and
a second voltage detection resistor connected electrically between the second resistor and the first voltage detection resistor and having a resistance value lower than the second resistor, and
wherein the semiconductor device comprises:
a plurality of third dummy wiring lines respectively coupled capacitively to the plurality of resistance layers in the first voltage detection resistor; and
a plurality of fourth dummy wiring lines respectively coupled capacitively to the plurality of resistance layers in the second voltage detection resistor.

5. The semiconductor device according to claim 1, wherein a resistance value between the first electrode and the second electrode is 1 MΩ or more and 1000 MΩ or less.

6. The semiconductor device according to claim 5, wherein a material of the resistance layers constituting the resistor includes at least one metal compound selected from the group consisting of CrSi, CrSiN, CrSiO, TaN, and TiN.

7. The semiconductor device according to claim 1, wherein a material of the first dummy wiring lines includes Al, Cu, W, or Ti.

8. The semiconductor device according to claim 1, further comprising a ring-shaped conductor arranged to surround the resistor in a plan view and embedded in the insulating layer,
wherein a shortest distance ΔY (μm) between the plurality of first dummy wiring lines and the ring-shaped conductor is set to satisfy: Vα (V)/100 (V/μm)≤ΔY (μm),
where Vα (V) is a magnitude of a voltage between a potential of one of the first dummy wiring lines that gives the shortest distance ΔY and a ground potential.

9. A semiconductor device, comprising:
a semiconductor substrate;
an insulating layer provided on the semiconductor substrate;
a resistor embedded in the insulating layer and formed by electrically connecting a plurality of resistance layers;
a first electrode connected electrically to a first end of the resistor;
a second electrode connected electrically to a second end of the resistor; and
a plurality of first dummy resistance layers arranged around the first electrode and respectively coupled capacitively to the plurality of resistance layers in the resistor.

10. A semiconductor device, comprising:
a semiconductor substrate;
an insulating layer provided on the semiconductor substrate;
a resistor embedded in the insulating layer and formed by electrically connecting a plurality of resistance layers;
a first electrode connected electrically to a first end of the resistor;
a second electrode connected electrically to a second end of the resistor; and
a plurality of first dummy wiring lines arranged around the first electrode and respectively connected electrically to the plurality of resistance layers in the resistor.

11. The semiconductor device according to claim 10,
wherein one dummy wiring line of the plurality of first dummy wiring lines is connected electrically to a first location of a first resistance layer among the plurality of resistance layers,
wherein another dummy wiring line of the plurality of first dummy wiring lines is connected electrically to a second location different from the first location among the plurality of resistance layers, and
wherein an end of the one dummy wiring line opposite the first location and an end of the other dummy wiring line opposite the second location face each other with a gap therebetween.

12. The semiconductor device according to claim 10,
wherein the resistor comprises:
a first resistor connected electrically to the first electrode;
a second resistor connected electrically to the second electrode; and
a voltage detection resistor that electrically connects the first resistor and the second resistor and has a resistance value lower than both the first resistor and the second resistor, and
wherein the semiconductor device comprises a first output electrode, a second output electrode, and a reference electrode, which are respectively connected electrically to different locations of the voltage detection resistor.

13. The semiconductor device according to claim 11,
wherein the resistor comprises:
a first resistor connected electrically to the first electrode;
a second resistor connected electrically to the second electrode; and
a voltage detection resistor that electrically connects the first resistor and the second resistor and has a resistance value lower than both the first resistor and the second resistor, and
wherein the semiconductor device comprises a first output electrode, a second output electrode, and a reference electrode, which are respectively connected electrically to different locations of the voltage detection resistor.

14. The semiconductor device according to claim 12, further comprising a plurality of second dummy wiring lines arranged around the second electrode and respectively connected electrically to the plurality of resistance layers in the second resistor,
wherein the plurality of first dummy wiring lines is respectively connected electrically to the plurality of resistance layers in the first resistor.

15. The semiconductor device according to claim 13, further comprising a plurality of second dummy wiring lines arranged around the second electrode and respectively connected electrically to the plurality of resistance layers in the second resistor,
wherein the plurality of first dummy wiring lines is respectively connected electrically to the plurality of resistance layers in the first resistor.

16. The semiconductor device according to claim 14,
wherein the voltage detection resistor comprises:
a first voltage detection resistor connected electrically to the first resistor and having a resistance value lower than the first resistor; and
a second voltage detection resistor connected electrically between the second resistor and the first voltage detection resistor and having a resistance value lower than the second resistor, and
wherein the semiconductor device comprises:
a plurality of third dummy wiring lines connected electrically to the plurality of resistance layers in the first voltage detection resistor, respectively; and
a plurality of fourth dummy wiring lines respectively connected electrically to the plurality of resistance layers in the second voltage detection resistor.

17. The semiconductor device according to claim 15,
wherein the voltage detection resistor comprises:
a first voltage detection resistor connected electrically to the first resistor and having a resistance value lower than the first resistor; and
a second voltage detection resistor connected electrically between the second resistor and the first voltage detection resistor and having a resistance value lower than the second resistor, and
wherein the semiconductor device comprises:
a plurality of third dummy wiring lines respectively connected electrically to the plurality of resistance layers in the first voltage detection resistor,; and
a plurality of fourth dummy wiring lines respectively connected electrically to the plurality of resistance layers in the second voltage detection resistor.

18. The semiconductor device according to claim 10, wherein a resistance value between the first electrode and the second electrode is 1 MΩ or more and 1000 MΩ or less.

19. The semiconductor device according to claim 18, wherein a material of the resistance layers constituting the resistor includes at least one metal compound selected from the group consisting of CrSi, CrSiN, CrSiO, TaN, and TiN.

20. The semiconductor device according to claim 10, wherein a material of the first dummy wiring lines includes Al, Cu, W, or Ti.

21. The semiconductor device according to claim 10, further comprising a ring-shaped conductor arranged to surround the resistor in a plan view and embedded in the insulating layer,
wherein a shortest distance ΔY (μm) between the plurality of first dummy wiring lines and the ring-shaped conductor is set to satisfy: Vα (V)/100 (V/μm)≤ΔY (μm),
where Vα (V) is a magnitude of a voltage between a potential of one of the first dummy wiring lines that gives the shortest distance ΔY and a ground potential.

22. A semiconductor device, comprising:
a semiconductor substrate;
an insulating layer provided on the semiconductor substrate;
a resistor embedded in the insulating layer and formed by electrically connecting a plurality of resistance layers;
a first electrode connected electrically to a first end of the resistor;
a second electrode connected electrically to a second end of the resistor; and
a plurality of first dummy resistance layers arranged around the first electrode and respectively connected electrically to the plurality of resistance layers in the resistor.
